(19) United States
(12) Patent Application Publication
(10) Pub. No.: US 2017/0003925 A1
(43) Pub. Date: Jan. 5, 2017

(54) Modular Interlocking Display System

(71) Applicant: ACASS Systems LLC, Omaha, NE (US)

(72) Inventor: Aaron D. Cass, Omaha, NE (US)

(21) Appl. No.: 15/200,643

(22) Filed: Jul. 1, 2016

Related U.S. Application Data
(60) Provisional application No. 62/187,749, filed on Jul. 1, 2015.
(60) Provisional application No. 62/187,741, filed on Jul. 1, 2015.
(60) Provisional application No. 62/192,780, filed on Jul. 15, 2015.

(51) Int. Cl. G06F 3/14; H05K 5/02; H05K 5/00

(52) U.S. Cl. CPC G06F 3/1446; H05K 5/0017; H05K 5/0221; H05K 5/0256

(57) ABSTRACT

A modular interlocking display system incorporates revolving latches, alignment guides, interlocking finger joints, and registration side-lock blocks to securely and rigidly link multiple modular units. The display system may include groups of modular display panels with bi-level locking to secure the display panels individually and as a group to a support frame of the display system to provide indoor and outdoor large-scale display. Tight tolerances are maintained during assembly in order to minimize gaps and deflections between display panels and to maximize resolution. The latches may include different types and configurations of revolving latches. The modular units may be positioned together to obtain almost any configuration while simultaneously being rigidly and securely interlocked.

The present application is related to and claims the benefit of the earliest available effective filing date(s) from the following listed application(s) (the “Related applications”) (e.g., claims earliest available priority dates for other than provisional patent applications or claims benefits under 35 USC §119(e) for provisional patent applications, for any and all parent, grandparent, great-grandparent, etc. applications of the Related application(s)). All subject matter of the Related applications and of any and all parent, grandparent, great-grandparent, etc. applications of the Related applications is incorporated herein by reference to the extent such subject matter is not inconsistent herewith.

### RELATED APPLICATIONS

The present application constitutes a utility application of U.S. Patent Provisional Application No. 62/187,741, entitled TRIGGER RELEASE AND GASKET SEAL FOR DISPLAY MOUNT, naming Aaron Douglas Cass as inventor, filed Jul. 1, 2015, and U.S. Patent Provisional Application No. 62/192,780, entitled LATCHING DEVICE, naming Aaron Douglas Cass as inventor, filed Jul. 15, 2015, and U.S. Patent Provisional Application No. 62/187,749, entitled ROTATING LATCH, naming Aaron Douglas Cass as inventor, filed Jul. 1, 2015.

### BACKGROUND

Modular systems configured for both large-scale and small-scale display allow for visual variety in the display experience. However, with an increasing number of modular units inter-linked, large-scale modular systems can pose safety risks if linking mechanisms fail or otherwise do not provide secure, rigid links. Further, gaps and deflection between panels pose a serious detriment to image quality, image resolution and to the overall visual experience offered by such systems.

Many events that use modular, large-scale display systems include band tours, state fairs and other performances, which are often outdoors. Outdoor conditions present varied weather conditions and probable electrical disruption due to circulating dust and debris. These same events require frequent assembling, disassembling, loading and unloading. Unavoidable, frequent transit of modular components presents opportunities for misalignment to the modular display system or its individual components. Even thermal expansion can result misalignment and gaps, posing a serious detriment to large-scale high-quality, high-resolution display systems.

Further, when individual components become damaged or malfunction during a performance, overly-complex or retrofitted designs necessitate prolonged disruption to the performance while replacement and reparation takes place. Replacing or repairing damaged or malfunctioning equipment on an unplanned basis costs significantly more than regular, routine maintenance repairs.

Further, interlocking mechanisms for large-scale display systems are either too complex or do not provide sufficiently rigid and secure support.

Therefore, it is desirous to obtain more robust, secure and otherwise improved modular display systems, methods, apparatuses and interlocking mechanisms that are simplified, quickly and easily repairable and provide sufficiently rigid and secure support.

### SUMMARY

In one aspect, the inventive concepts disclosed herein are directed to a modular display unit configured for indoor or outdoor use. In a further aspect, the modular display unit may include a support frame. In a further aspect, the modular display unit may include an interlocking latch coupled to the support frame. In a further aspect, the modular display unit may include an alignment guide positioned on a first side of the support frame and an alignment guide hole positioned on a second side of the support frame. In a further aspect, the modular display unit may include a registration side-lock block positioned on a side orthogonal to the first side of the support frame. In a further aspect, the modular display unit may include a group of modular display panels removably coupled with an interfacing power supply and removably coupled to the support frame. In a further aspect, the modular display unit may include a memory configured to store computer executable code. In a further aspect, the modular display unit may include a controller in communication with the memory and the interfacing power supply, the controller configured to access the executable code to perform and direct rendering and presenting of a display on the group of modular display panels.

In another aspect, the inventive concepts disclosed herein are directed to a multi-support frame system. In a further aspect, the multi-support frame system may include a support structure made up of multiple support frames. In a further aspect, the multi-support frame system may include a first support frame of the multiple support frames including a revolving, interlocking latch, an alignment guide to align the first support frame with a second support frame in a first direction, a registration side-lock block to align the first support frame with a third support frame in a second direction, and a side support beam having tapered fingers on a first end of the side support beam and coinciding depressions on a second end of the side support beam, the depressions coinciding in shape to the tapered fingers.

In another aspect, the inventive concepts disclosed herein are directed to a method for obtaining or maintaining strict system dimension tolerances. In a further aspect, the method may include forming a first support frame having multiple sides including an alignment notch located at a midpoint of a side of the multiple sides. In a further aspect, the method may include measuring one or more dimensions of the first support frame relative to the alignment notch. In a further aspect, the method may include removing a portion of a facial surface of a side of the multiple sides of an assembled first support frame if the one or more dimensions is not within a first predetermined dimension tolerance. In a further aspect, the method may include interlocking a second support frame with the first support frame according to a second predetermined dimension tolerance.

In another aspect, the inventive concepts disclosed herein are directed to a revolving latch for adjoining two opposing surfaces. In a further aspect, the revolving latch may include a shaft. In a further aspect, the revolving latch may include a shaft head including a portion extending beyond a circumference of the shaft. In a further aspect, the revolving latch may include a receiving plate with a cut-out portion configured to allow the shaft head to extend through the cut-out portion of the receiver plate when in a first rotational position and to inhibit the shaft head from extending through the cut-out portion of the receiver plate when in a second rotational position. In a further aspect, the revolving latch may include a revolving mechanism operably attached to the shaft and shaft head to revolve the shaft head simultaneous with at least one of extending and retracting the shaft head. In a further aspect, the revolving latch may include a locking mechanism to lock the revolving mechanism in an extended position and restrict movement of the shaft head or the revolving mechanism.

In another aspect, the inventive concepts disclosed herein are directed to a revolving latch system. In a further aspect, the revolving latch system may include one or more revolving latches and a receiving plate. In a further aspect, a revolving latch of the one or more revolving latches may include: an extending and retracting shaft having a generally cylindrical shape and a portion that extends beyond the shaft; a receiving compartment with a cut-out portion having a substantially similar shape to a shape of the portion that extends beyond a circumference of the shaft, wherein a perimeter of the cut-out portion is slightly larger than a perimeter of the portion that extends beyond the circumference of the shaft; a revolving mechanism operably attached to the shaft to revolve the portion that extends beyond the shaft simultaneous with at least one of extending and retracting; and a locking mechanism to lock the shaft in at least one of an extended position and retracted position.

In another aspect, the inventive concepts disclosed herein are directed to a latch. In a further aspect, the latch may include a base defining an opening having a plurality of radially extending apertures spaced apart from one another and extending from the center of the opening, and a first plurality of radially extending protrusions spaced between respective ones of the plurality of radially extending apertures and extending toward the center of the opening. In a further aspect, the latch may include a shaft head having a second plurality of radially extending protrusions spaced apart from one another and extending from the center of the shaft head. In a further aspect, the latch may include a shaft coupled with the base and configured to extend the shaft head through the opening when the second plurality of radially extending protrusions is aligned with the plurality of radially extending apertures.

In another aspect, the inventive concepts disclosed herein are directed to a modular, interlocking staging system. In a further aspect, the modular, interlocking staging system may include a plurality of support beams. In a further aspect the modular, interlocking staging system may include a plurality of revolving latches, a revolving latch of the plurality of revolving latches comprising a revolving mechanism, an extendable and retractable shaft, and a releasing-locking mechanism, the revolving mechanism being integrated with a first support beam of the plurality of support beams to interlock the first support beam with a second support beam when the shaft is extended, revolved in a first direction, and then retracted, the releasing-locking mechanism configured to release the interlock of the first support beam and the second support beam. In another aspect, the modular, interlocking staging system is configured to incorporate one or more display panels.

In another aspect, the inventive concepts disclosed herein are directed to a method for creating proper spacing between display panels of a modular, interlocking display system. In a further aspect, the method may include determining a thermal expansion coefficient for a modular display panel. In a further aspect, the method may include determining a change in a dimension of the modular display panel due to temperature change in the modular display panel, the change determined using the thermal expansion coefficient. In a further aspect, the method may include determining a spacing that should exist between two or more assembled modular display panels. In a further aspect, the method may include determining and providing instructions for assembling a modular interlocking display system according to the spacing that should exist between the two or more assembled modular display panels.

### BRIEF DESCRIPTION OF THE DRAWINGS

Implementations of the inventive concepts disclosed herein may be better understood when consideration is given to the following detailed description thereof. Such description makes reference to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1 shows a block diagram of an embodiment of a modular interlocking display system, according to the inventive concepts of the present disclosure;

FIG. 2 shows a perspective view of an embodiment of a modular interlocking display system, according to the inventive concepts of the present disclosure;

FIG. 3 shows a side view of an embodiment of a modular interlocking display system, according to the inventive concepts of the present disclosure;

FIG. 4 shows a back view of an embodiment of a modular interlocking display system, according to the inventive concepts of the present disclosure;

FIG. 5 shows a front view of an embodiment of a modular interlocking display system, according to the inventive concepts of the present disclosure;

FIG. 6 shows a back view of an embodiment of a modular transport, according to the inventive concepts of the present disclosure;

FIG. 7 shows a side view of an embodiment of a modular transport, according to the inventive concepts of the present disclosure;

FIG. 8 shows a back view of an embodiment of a modular display unit with a support frame, two display panel groups, and two power supplies, according to the inventive concepts of the present disclosure;

FIG. 9 shows a back view of an embodiment of a support frame, according to the inventive concepts of the present disclosure;

FIG. 10 shows a back view of an embodiment of two support frames, according to the inventive concepts of the present disclosure

FIG. 11 shows a side view of an embodiment of a support frame and multiple embodiments of fingers and coinciding depressions, according to the inventive concepts of the present disclosure;

FIG. 12 shows a side schematic view of an embodiment of a support frame, according to the inventive concepts of the present disclosure;

FIG. 13 shows an embodiment of a display panel group, according to the inventive concepts of the present disclosure;

FIG. 14 shows a close-up view of an embodiment of a display panel group attached to a support frame, according to the inventive concepts of the present disclosure;

FIG. 15 shows a close-up view of an embodiment of a group locking mechanism including a weather seal and lever, according to the inventive concepts of the present disclosure;

FIG. 16 shows a side view of an embodiment of an individual locking mechanism, according to the inventive concepts of the present disclosure;

FIG. 17 shows a back view of a display panel, according to the inventive concepts of the present disclosure;

FIG. 18 shows a perspective view and a side view of corner block, according to the inventive concepts of the present disclosure;

FIG. 19 shows a perspective view of a corner block and receiver plate, according to the inventive concepts of the present disclosure;

FIG. 20 shows a perspective view of embodiments of two revo-latches configured to be integrated with a corner block of a support frame and a receiving plate of another support frame, according to the inventive concepts of the present disclosure;

FIG. 21 shows a perspective view of an embodiment of a position of a revo-latch, according to the inventive concepts of the present disclosure;

FIG. 22 shows a perspective view of an embodiment of another position of a revo-latch, according to the inventive concepts of the present disclosure;

FIG. 23 shows a perspective view of another embodiment of another position of a revo-latch, according to the inventive concepts of the present disclosure;

FIG. 24 shows a perspective view of an embodiment of a revo-latch assembly, according to the inventive concepts of the present disclosure;

FIG. 25 shows a front-perspective view of an embodiment of a latch, according to the inventive concepts of the present disclosure;

FIG. 26 shows a back-perspective view of an embodiment of a latch, according to the inventive concepts of the present disclosure;

FIG. 27 shows a front-perspective view of an embodiment of a latch, according to the inventive concepts of the present disclosure;

FIG. 28 shows a shows a back-perspective view of an embodiment of a latch, according to the inventive concepts of the present disclosure;

FIG. 29 shows a front-perspective view and a back-perspective view of an embodiment of two latches, according to the inventive concepts of the present disclosure;

FIG. 30 shows a perspective view of an embodiment of two interlocked latches, according to the inventive concepts of the present disclosure;

FIG. 31 shows a perspective view of an embodiment of an interlocking latch assembly, according to the inventive concepts of the present disclosure;

FIG. 32 shows a perspective view of an embodiment of an interlocking latch assembly, according to the inventive concepts of the present disclosure;

FIG. 33 shows a perspective view of an embodiment of an interlocking latch assembly, according to the inventive concepts of the present disclosure;

FIG. 34 shows a perspective view of an embodiment of an interlocking latch assembly, according to the inventive concepts of the present disclosure;

FIG. 35 shows a perspective view of an embodiment of an interlocking latch assembly, according to the inventive concepts of the present disclosure;

FIG. 36 shows a perspective view of an embodiment of an interlocking latch assembly, according to the inventive concepts of the present disclosure;

FIG. 37 shows a perspective view of an embodiment of an interlocking latch assembly, according to the inventive concepts of the present disclosure;

FIG. 38 shows a perspective view of an embodiment of an interlocking latch assembly, according to the inventive concepts of the present disclosure;

FIG. 39 shows a cross-sectional isometric view illustrating an interlocking latch, such as the latch illustrated in FIG. 24, where the interlocking latch is shown in a retracted position, according to the inventive concepts of the present disclosure;

FIG. 40 shows a cross-sectional isometric view illustrating an interlocking latch, such as the interlocking latch illustrated in FIG. 24, where the interlocking latch is shown in an extended position, according to the inventive concepts of the present disclosure;

FIG. 41 shows a cross-sectional isometric view illustrating an interlocking latching system, including a first interlocking latch and a second interlocking latch, such as two interlocking latches as illustrated in FIG. 24, where the latching system is shown in a secured orientation, according to the inventive concepts of the present disclosure;

FIG. 42 shows a side, cross-sectional isometric view illustrating an interlocking latching system, including a first interlocking latch and a second interlocking latch, such as two interlocking latches as illustrated in FIG. 24, where the latching system is shown in a secured orientation, according to the inventive concepts of the present disclosure;

FIG. 43 shows an embodiment of a method for determining appropriate panel spacing, according to the inventive concepts of the present disclosure; and

FIG. 44 shows an embodiment of a method for maintaining strict alignment and spacing tolerances, according to the inventive concepts of the present disclosure.

### DETAILED DESCRIPTION OF EXEMPLARY EMBODIMENTS

Before explaining at least one embodiment of the inventive concepts disclosed herein in detail, it is to be understood that the inventive concepts are not limited in their application to the details of construction and the arrangement of the components or steps or methodologies set forth in the following description or illustrated in the drawings. In the following detailed description of embodiments of the instant inventive concepts, numerous specific details are set forth in order to provide a more thorough understanding of the inventive concepts. However, it will be apparent to one of ordinary skill in the art having the benefit of the instant disclosure that the inventive concepts disclosed herein may be practiced without these specific details. In other instances, well-known features may not be described in detail to avoid unnecessarily complicating the instant disclosure. The inventive concepts disclosed herein are capable of other embodiments or of being practiced or carried out in various ways. Also, it is to be understood that the phraseology and terminology employed herein is for the purpose of description and is not meant to be limiting.

Further, unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present).

Reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

“Large-scale” as used herein with respect to a modular interlocking display system means multiple (e.g., two or more) modular display units linked together to form a single display system.

“Small-scale” as used herein means a single modular display unit, or less (e.g., one or more display panels that are not a part of a group of display panels) to form a separate visual aspect of a modular interlocking display system.

Broadly, modular interlocking display systems, methods and apparatuses are disclosed. In an exemplary embodiment, the modular interlocking display system is designed for both small- and large-scale use, and is configurable to obtain almost any visual arrangement. Modular units of the system are securely interlocked with at least another modular unit or a support structure, using novel structurally-reinforced, orthogonal linking mechanisms and keyed, registration side-lock blocks. The light-weight frames, fixed rigidity and minimal machining tolerances of each modular unit ensure maximum safety despite large numbers of stacked or linked units. Further, as display panels are brought together to create near seamless adjoining surfaces, gaps and deflection between panels are minimized, contributing to the highest image quality and highest image resolution desired.

Bi-level locking mechanisms increase weather protection, while allowing replacement of individual panels even during real-time use. Because each grouping of panels incorporates a pass-through power supply, the remainder of panels in the grouping continue to function while the individual panel is replaced.

Further, by incorporating multiple, smaller levels of modularity, higher resolutions are obtained and critical components become individually replaceable without significant image loss. Still further, by making the modular designs more user-friendly, each level of modularity is quickly and easily replaceable.

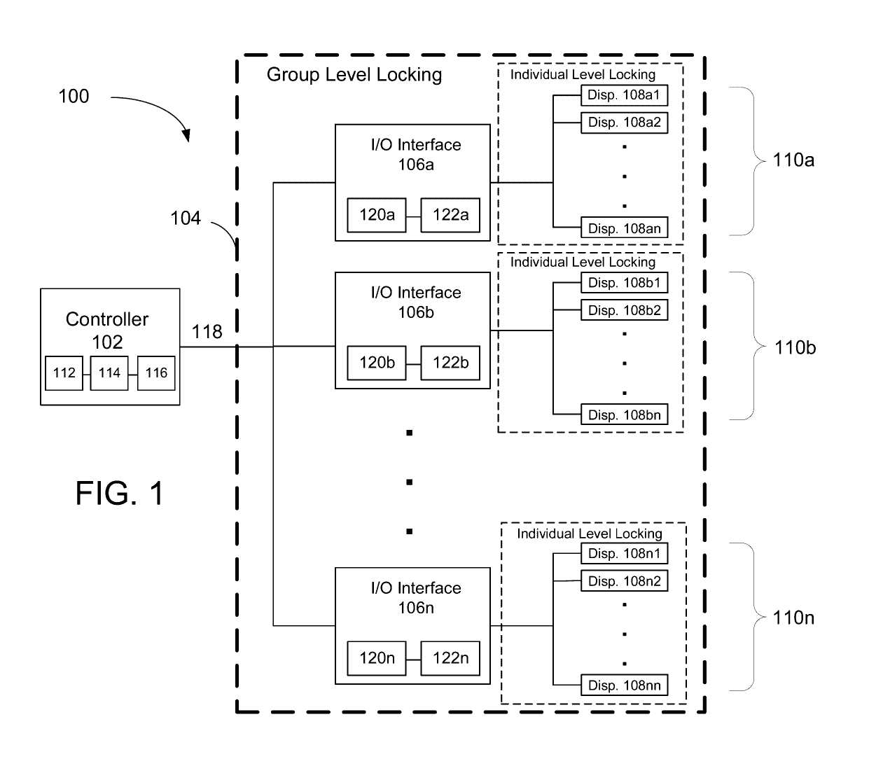

Referring now to FIG. 1, an exemplary embodiment of a modular interlocking display system 100 may include a controller 102, a support structure 104, an input/output (I/O) interface 106, and one or more modular display panels 108. In an exemplary embodiment, the one or more modular display panels 108 may include multiple display panels, which are each arranged in one or more display panel groups 110. In an exemplary embodiment, the I/O interface 106 may include multiple I/O interfaces (e.g., 106a to 106n) corresponding to each of the one or more display panel groups (e.g., 110a to 110n).

In an exemplary embodiment, the multiple I/O interfaces 106a to 106n are coupled to the support structure 104 via group level locking. Further, each display panel 108 of the one or more display panel groups 110a to 110n is coupled to the support structure 104 via individual level locking.

In an exemplary embodiment, the controller 102 may include memory 112, first input means 114 and first output means 116. The first input means 114 may include one or more processors (e.g., CPU, display processor, or combinations thereof), a receiver (e.g., transceiver), an internal bus, and one or more user input devices (e.g., keyboard, mouse, haptic input device, microphone, or combinations thereof) in communication with the one or more processors. The one or more processors are in communication with the memory 112. The first output means 116 may include one or more output ports, a modulator, a digital to analog converter, a transmitter, and an external bus. In an exemplary embodiment, the controller has a frame rate of greater than or equal to 1920 Hz (e.g., refresh rate).

In an exemplary embodiment, the controller 102 utilizes one or more communication links 118 (e.g., electrical, optical, wired, wireless, or combinations thereof) to communicate with controller/display I/O interface(s) 106. The communication link 118 can connect the controller 102 and the I/O interface(s) 106 to a network, including but not limited to, a Local Area Networks (LAN) (e.g., an Ethernet or corporate network), a Wide Area Network (WAN) (e.g., the Internet), a wireless data network, a fiber optical network, a radio frequency communications network, another electronic data network, or combinations thereof.

In an exemplary embodiment, the I/O interface 106 may include second input means 120 and second output means 122. The input means 120 may include a receiver, a demodulator, one or more filters, logic circuitry (e.g., input/header processor), on or more input ports, a power supply (e.g., power supply 126, below), an input buffer, a link (e.g., fiber, coaxial cable, copper twisted-pair wire, wireless connection, or combinations thereof), or combinations thereof. The output means 122 may include a second external bus, a comparator, a display processor (e.g., front end and back end processor), an output buffer, an analog to digital converter, one or more output ports, or combinations thereof. It is noted that some embodiments disclosed herein use packet based digital communication, and as such, the use of an analog to digital converter or a digital to analog converter may be reduced or eliminated.

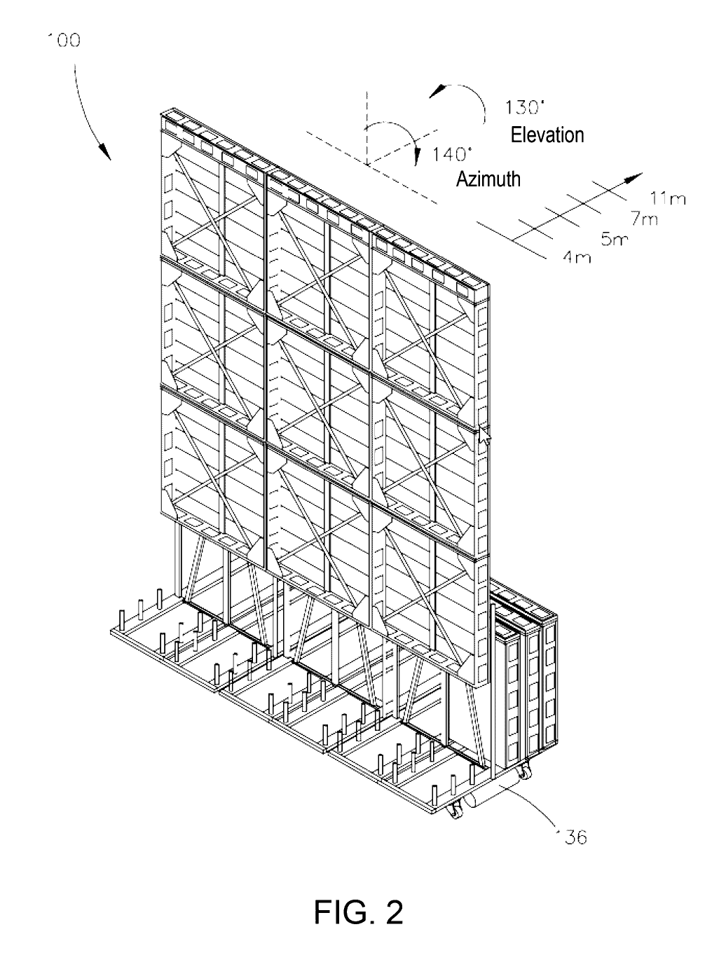

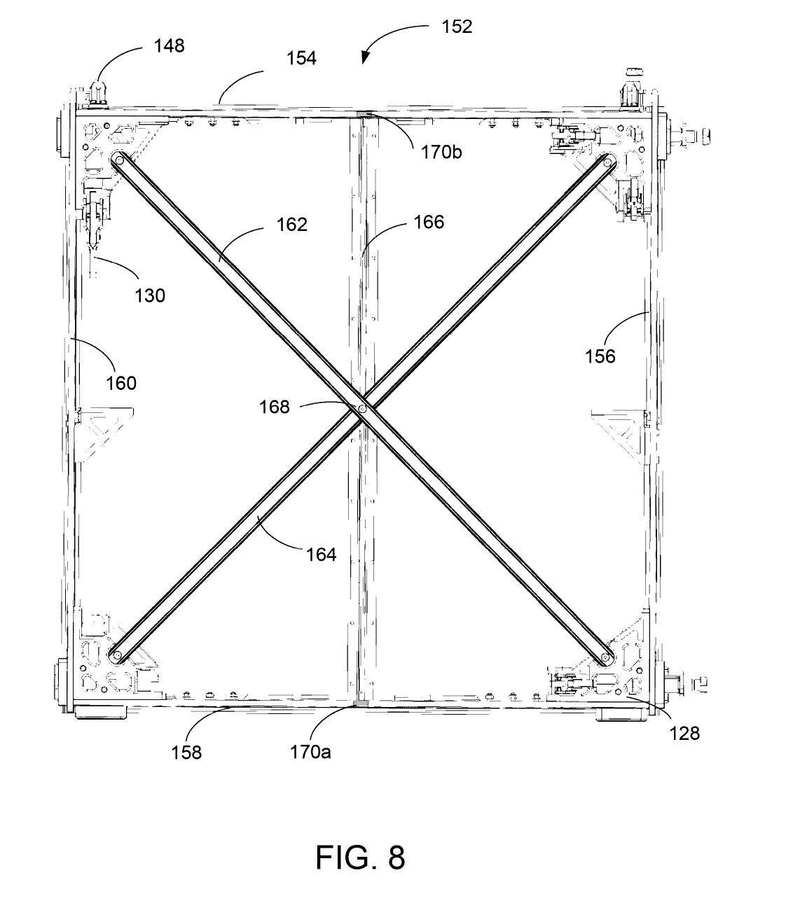

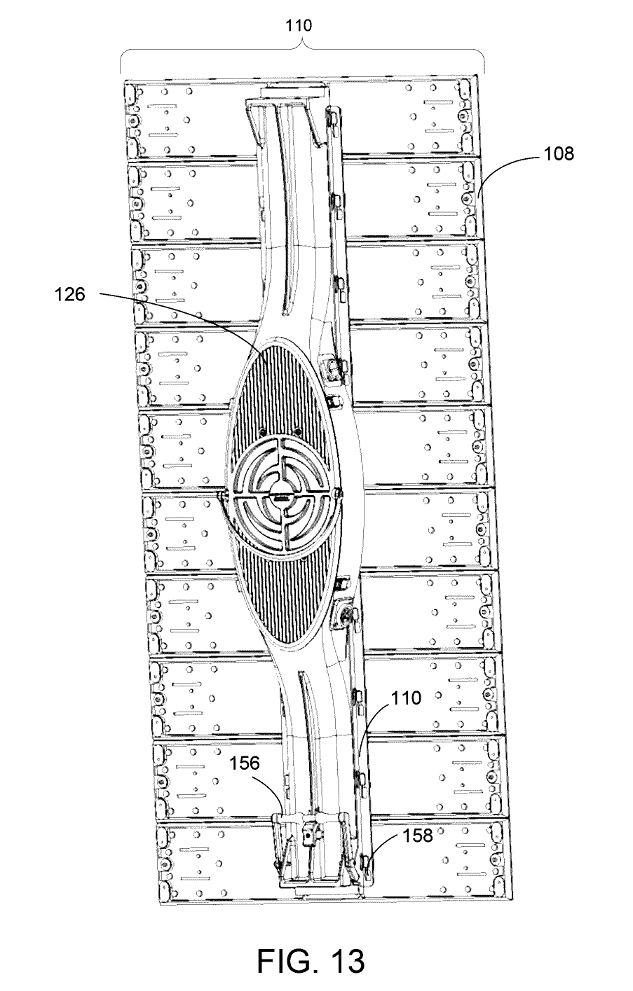

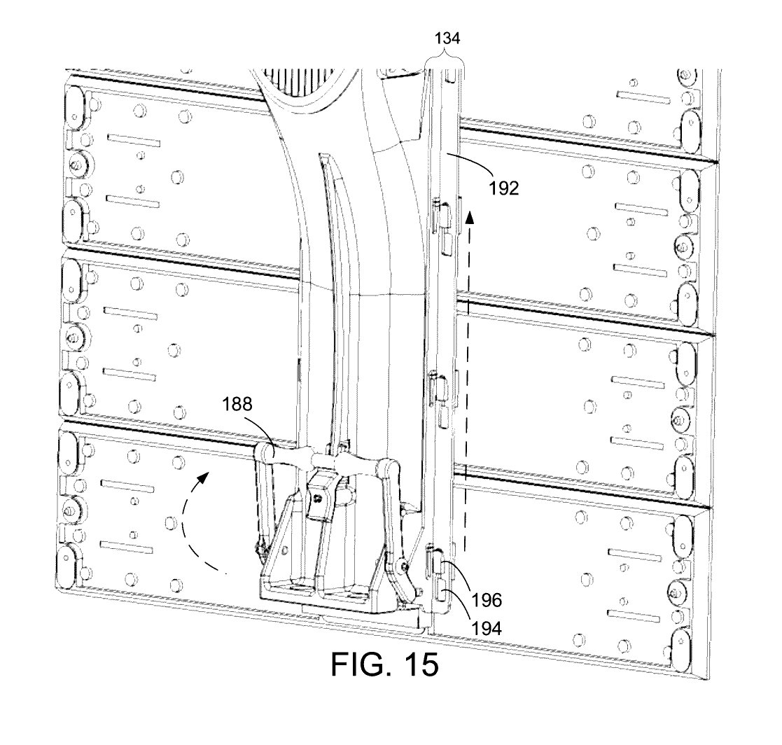

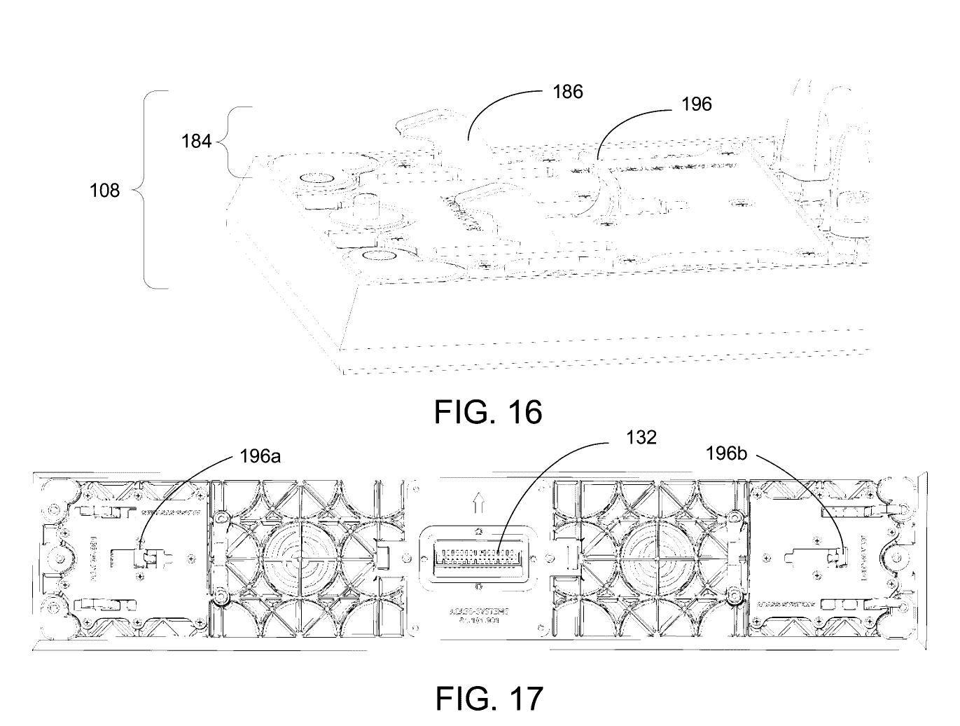

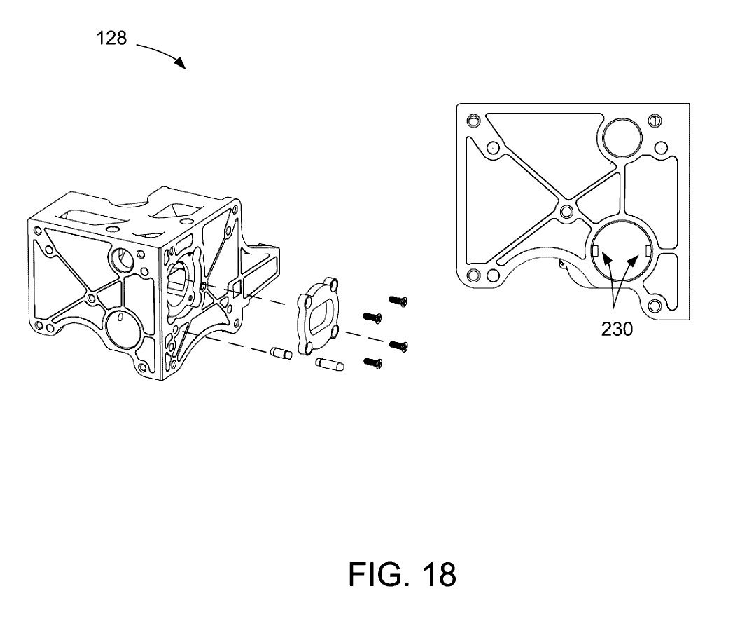

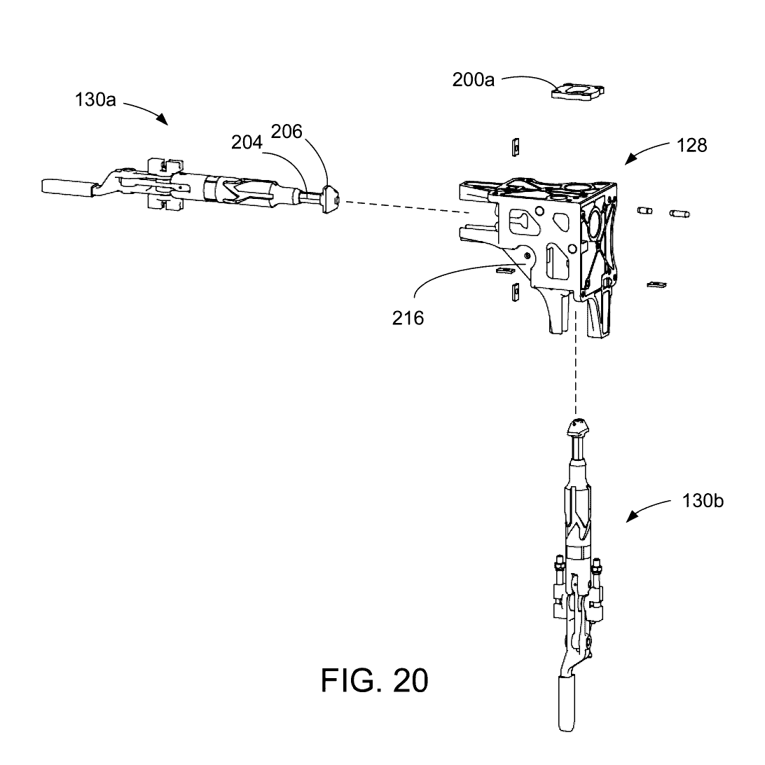

Referring generally now to FIGS. 2-20, exemplary embodiments of a modular interlocking display system 100 may include one or more modular display units 124 (see, for example, FIG. 8). In an exemplary embodiment, a modular display unit 124 may include one or more groups 110 of modular display panels 108, a power supply 126 (see, for example, FIG. 13) for each group 110 of display panels 108, and multiple corner blocks 128 (see, for example, FIG. 18) configured to integrate with one or more latches 130 (see, for example, FIG. 20). In an exemplary embodiment, the power supply 126 may include multiple interfacing ports (not shown) that coincide with input ports 132 (see, for example, FIG. 17 below) of the multiple modular display panels 108 and may include a group level locking weather seal 134 (see, for example, FIG. 15 below) surrounding the interfacing ports. In an exemplary embodiment, a modular display unit 124 may be transported using a modular transport 136. In an exemplary embodiment, the support structure 104 comprises a modular display unit 124 and a modular transport 136.

In an exemplary embodiment, the power supply 126 of a modular display unit 124 utilizes pass-through power, enabling an individual display panel 108 to be disengaged and removed from a display panel group 110, while the remainder of the display panels 108 of the group 110 may continue to operate (e.g., hot swappable). For example, a display panel 108 may incorporate a hot swappable input port 132 (below) or input connector, including but not limited to, Video Electronics Standards Association (VESA), VGA, DVI, FPD-Link, HDMI, DSC, 8P8C, RJ45, other 2×GB Ethernet-compliant connectors, or combinations thereof. In an exemplary embodiment, the power supply 126 utilizes alternating current (e.g., 110V to 220V+/−10%).

In an exemplary embodiment, the bi-level locking mechanisms, and other features (e.g., maintaining strict tolerances, type of materials used, or combinations thereof) of the modular interlocking display system 100 and methods disclosed herein, provide protection against contaminate and water intrusion. For example, an embodiment of the modular interlocking display system 100 may be rated with an Ingress Protection Marking, or IP Code rating, of IP65 (e.g., front and rear both rated at IP65).

With respect to the strict tolerances maintained by the modular interlocking display system 100 and methods disclosed herein, it is noted that because a resolution of a display is limited by the aspect ratio of the display (e.g., a 4:3 aspect ratio can obtain resolutions from: 640×480, 800×600, 960×720, etc.; a 16:10 aspect ratio can obtain resolutions from: 1280×800, 1440×900, 1680×1050, 1920×1200 and 2560×1600; and a 16:9 aspect ratio can obtain resolutions from: 1024×576, 1152×648, 1280×720, 1366×768, 1600×900, 1920×1080, 2560×1440 and 3840×2160), the dimensions of each modular display unit 124 and spacing between linked modular display units 124 are highly accurate to obtain highest possible resolutions.

In some embodiments, the display panel 108 is depicted as a light emitting diode (LED) display panel. It is noted that this depiction is not limiting. For example, the modular interlocking display system 100, the bi-level locking mechanisms, the controller 102, other components disclosed herein, and combinations thereof are configurable to function with a display panel 108 that may include, but is not limited to, a liquid crystal display (LCD), organic light emitting diode (OLED) display, other display technologies known in the art, or combinations thereof.

In an exemplary embodiment, the display panel 108 is sized to fit within a group 110 (see, for example, FIG. 13) of display panels 108. For example, a support frame 152 (below) may be sized as a 1000 mm×1000 mm×145 mm thick modular unit 102, such that twenty 500 mm (width)×100 mm (height) display panels 108 would be included in the group 110 of display panels 108.

In an exemplary embodiment, display panel 108 may have a pixel resolution of from 132 pixels (width)×26 pixels (height), 100 pixels (width)×20 pixels (height), 70 pixels (width)×14 pixels (height), to 45 pixels (width)×9 pixels (height), respectively resulting pixel densities of from 68640 pixels/m², 40,000 pixels/m², 19,600 pixels/m², and 8100 pixels/m².

In an exemplary embodiment, the display panel 108 may have a brightness from 3000 nit to 5000 nit, after calibration. In some embodiments, calibration may be done at an individual display panel 108 level. In other embodiments, calibration may be done at a panel group 150 level. In other embodiments calibration may be done on a modular unit 102 level or a modular interlocking display system 100 level.

In an exemplary embodiment, the display panel 108 may have a pixel pitch from 3.82 mm, 5 mm, 7.14 mm to 11.11 mm. In an exemplary embodiment, the display panel may use 3 in 1 surface mounted diode (SMD) 3535 Black Package LED technology (e.g., 3535=3.5 mm×3.5 mm). In another exemplary embodiment, the display panel may use 3 in 1 SMD 2727 Black Package LED technology. In another exemplary embodiment, the display panel may use 3 in 1 SMD 0402 LED technology. In another exemplary embodiment, the display panel may use 3 in 1 SMD 0201 LED technology. In an exemplary embodiment, the display panel 108 may include a driver for regulating power supplied to the light source (e.g., LEDs) of the display panel 108. For example, the driver may comprise an integrated circuit (IC) driver. For instance, the IC driver may be a Macroblock, Inc. (MBI) 5151 driver.

In an exemplary embodiment, the display panel 108 may be configured with a separate, individual hanging support (not shown) to create a small-scale display system that may be integrated together with a large-scale modular interlocking display system, enabling additional visual variety.

Referring now to FIG. 2, an exemplary embodiment of the modular interlocking display system 100 enables wide viewing angles. For example, a vertical viewing angle may be 130° and a horizontal viewing angle may be 140°. In an exemplary embodiment, the modular interlocking display system 100 is configured for minimum viewing distances from 4 m, 5 m, 7 m to 11 m.

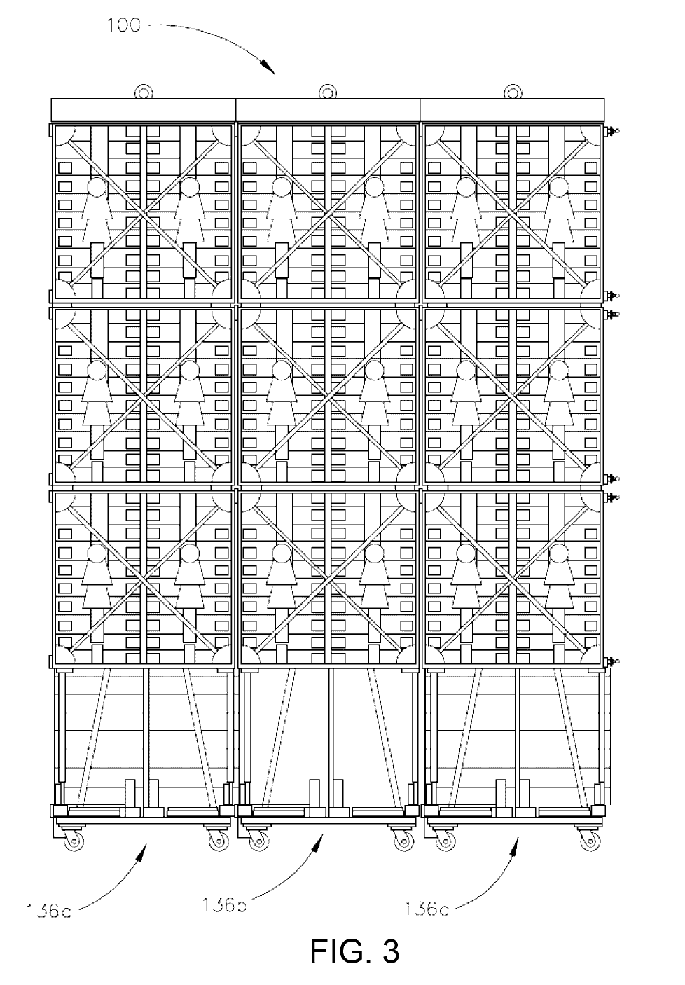

Referring now to FIG. 3, an exemplary embodiment of the modular interlocking display system 100 may include multiple modular transports 136 that may be coupled together. For example, a modular interlocking display system may include three modular transports, 136a, 136b, and 136c coupled together.

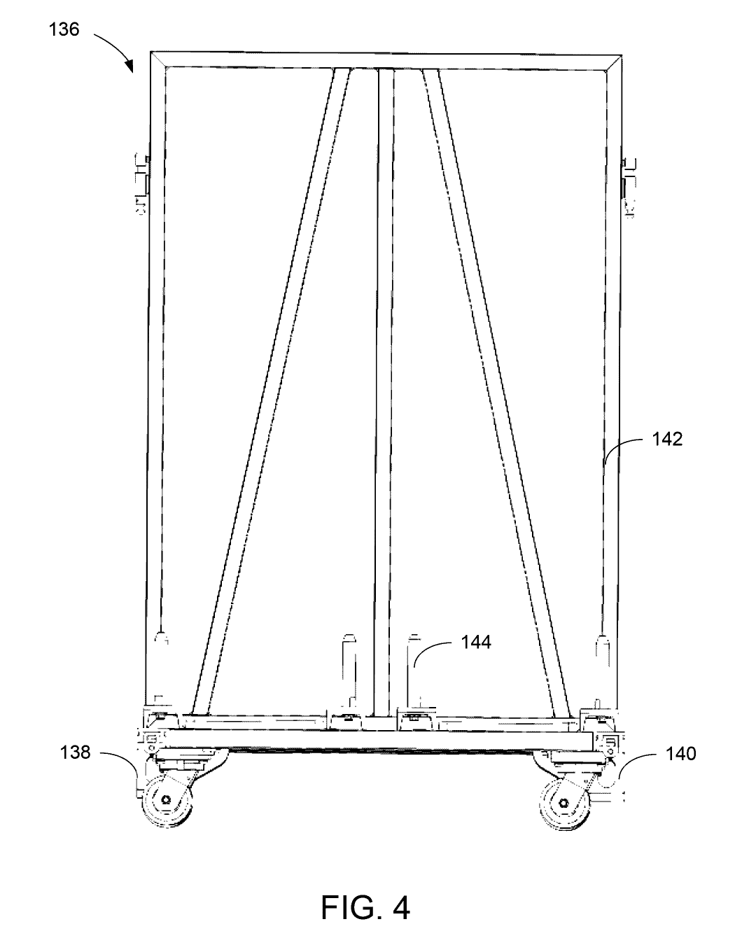

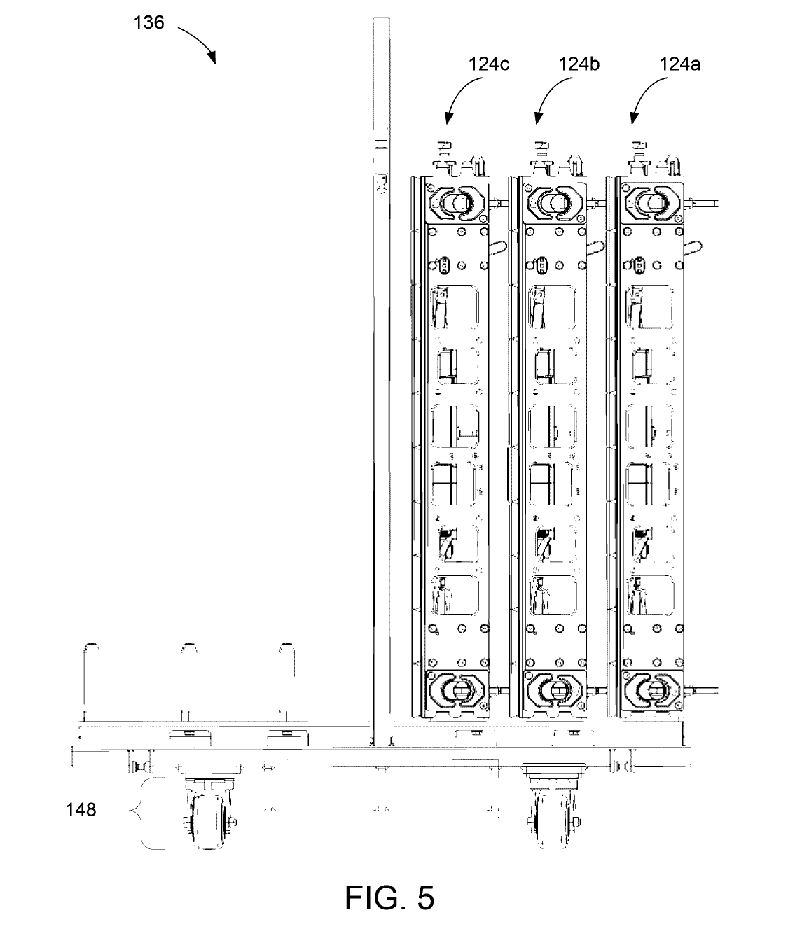

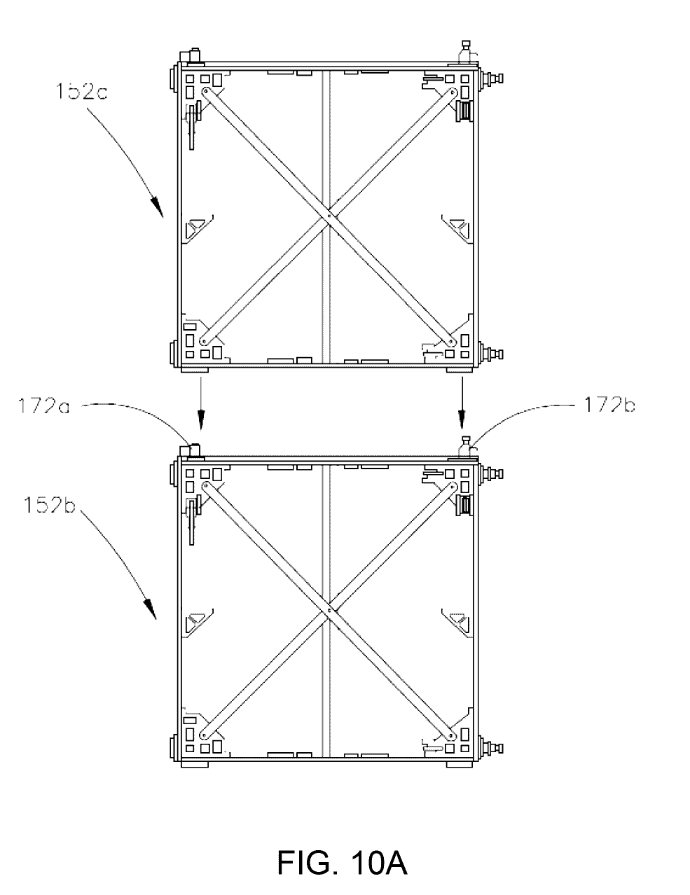

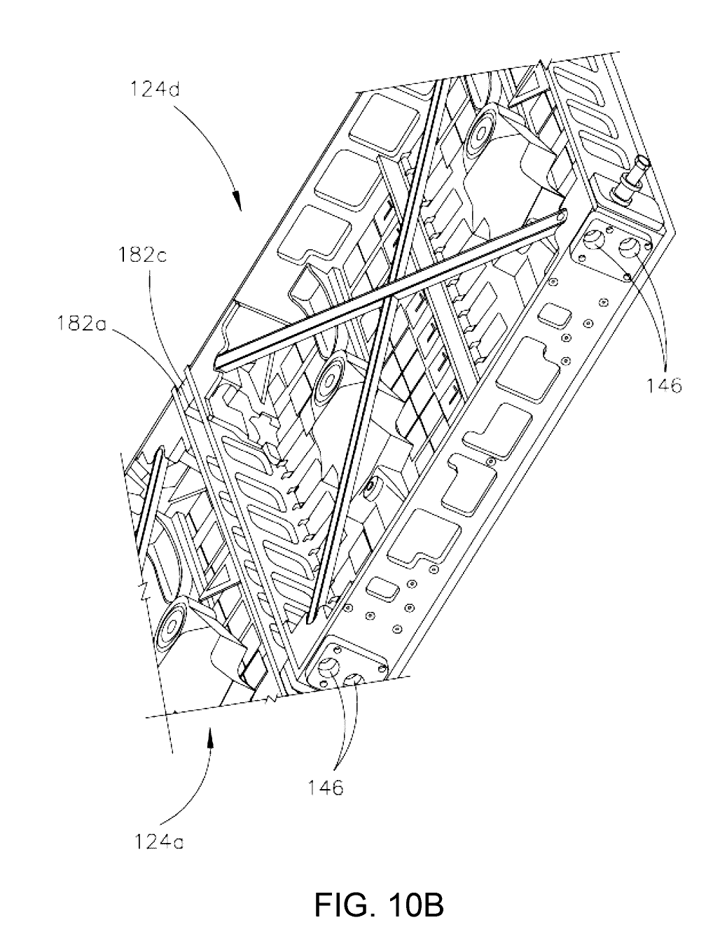

Referring now to FIGS. 4 and 5, a modular transport 136 may include a front coupler 138, a rear coupler 140, a transport support frame 142, and a transport alignment guide 144. In an exemplary embodiment, the modular transport 136 is configured transport multiple modular display units 124 (e.g., 124a, 124b, and 124c). In an exemplary embodiment, the transport alignment guide 144 is coupled to the transport support frame 142 to restrict horizontal, swaying movement so that display panels 108 of a first modular display unit (e.g., 124a) do not impact display panels 108 of a second modular display unit (e.g., 124b) during transport. The transport alignment guide 144 may be configured to be inserted through an alignment guide hole 146 (see, for example, FIG. 10) of a modular display unit 124, such that the modular transport 126 may be utilized as a support structure upon which multiple modular display units 124 (e.g., 124a, 124b, and 124c) may be linked to form a large-scale modular interlocking display system 100. In an exemplary embodiment, the transport alignment guide 144 and a corresponding alignment guide hole 146 are shaped to restrict horizontal movement, while being shaped to allow lateral movement. For example, the transport alignment guide 144 may have a tapered, cylindrical shape and the corresponding alignment guide hole 146 may have an elliptical shape, where a major axis of the elliptical shape allows lateral movement and a minor axis restricts the horizontal movement. In an exemplary embodiment, transport wheels 148 may include a locking mechanism to restrict movement of the wheels 148 of the modular transport 126.

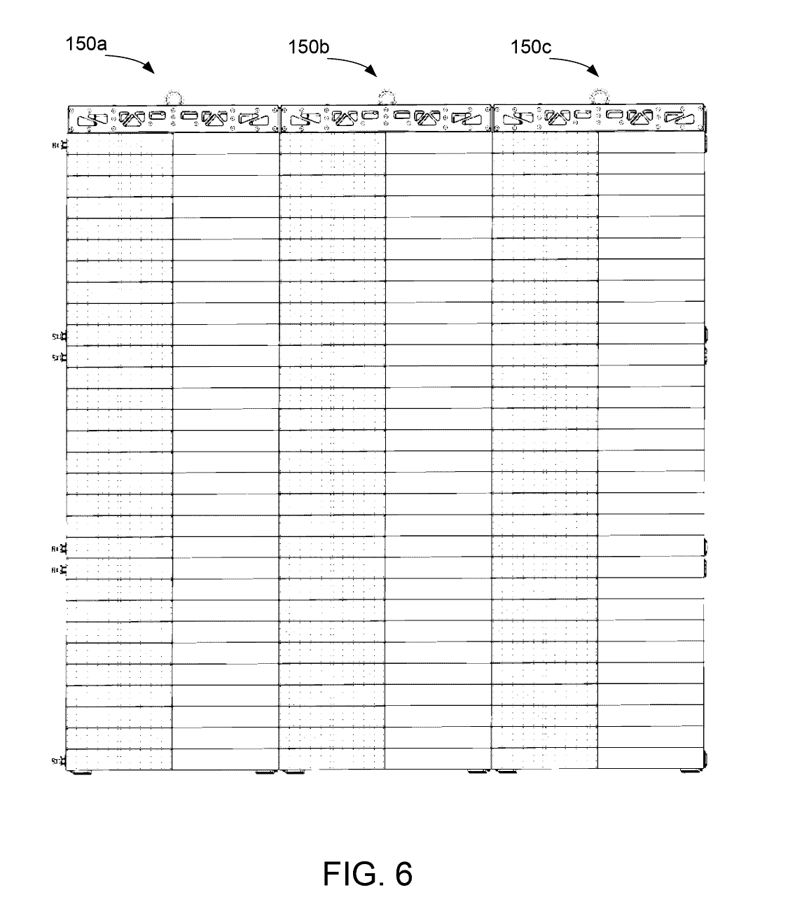

Referring now to FIG. 6, an exemplary embodiment of the modular interlocking display system 100 may include one or more hanging supports 150. In an exemplary embodiment, a hanging support 150 may be configured to mount to an individual modular display unit 124 and may coincide in number to a number of modular display units 124 linked together. For example, in FIG. 6 a front view of a 3×3 wall of modular display units 124 linked together is depicted. In this regard, the modular interlocking display system 100 may include three hanging supports 150a, 150b, and 150c. It is noted that while FIG. 6 depicts individual hanging support 150 with a load bearing ring, this depiction is not limiting. For example, a load bearing hook, bar, or other load bearing means may be coupled with a frame of the hanging support 150, which may be coupled to a modular unit 124 in order to hang the modular interlocking display system 100. In another exemplary embodiment, when the dimensions of a finalized modular interlocking display system 100 are predetermined, a hanging support 150d (not shown) is constructed to fit over multiple modular display units 124 in order to hang the modular interlocking display system 100.

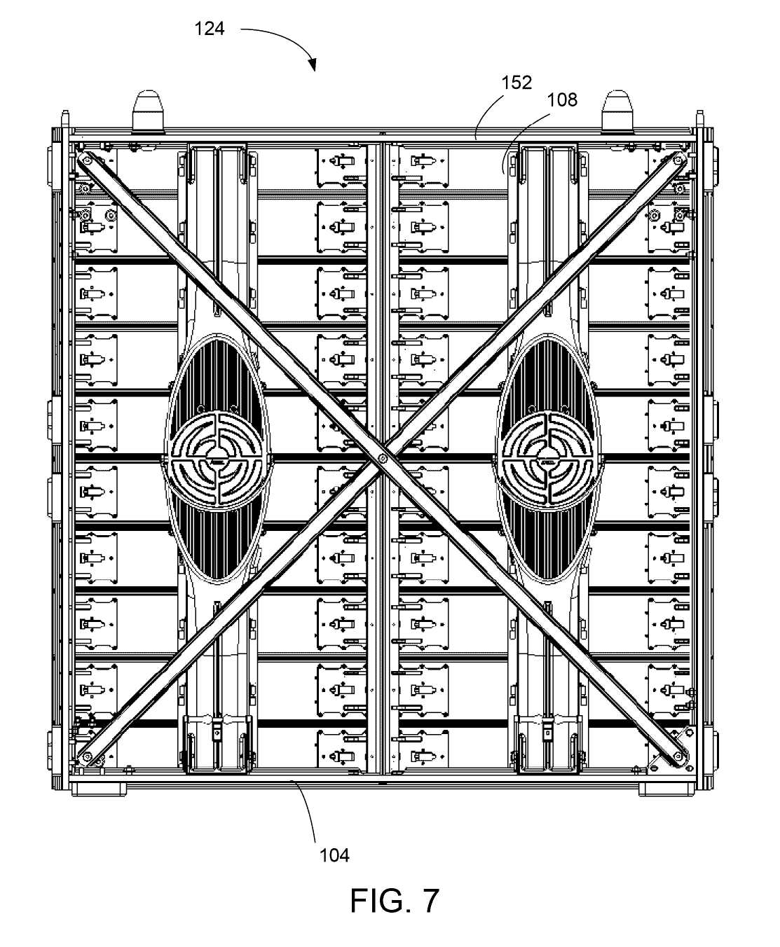

Referring now to FIG. 7, an exemplary embodiment of a modular display unit 124 may include a display support frame 152 and a modular display panel 108 removably coupled with the display support frame 152. In an exemplary embodiment, the display support frame 152 may be constructed of a strong, lightweight, rigid material. For example, in some embodiments, the display support frame 152, and/or components of the display support frame 152, may be constructed of a metal alloy. For instance, A356 T6 aluminum may be used because it has a relatively high tensile strength—207 MPa or 30.0 ksi. It is noted that the specific alloy used is not limiting. For example, other high strength, rigid materials may be used, including but not limited to, A201 T7 aluminum, A295 T6 or T62 aluminum, A328 T6 aluminum, A355 T71 aluminum, A771 T71 aluminum, other aluminum alloys, magnesium alloys, titanium alloys, beryllium alloys, carbon fiber materials (e.g., carbon fibers derived from polyacrylonitrile (PAN), reinforced carbon carbon (RCC), carbon-fiber-reinforced polymer (CFRP), carbon-fiber-reinforced plastic (CRP), carbon-fiber-reinforced thermoplastic (CFRTP), or combinations thereof), or combinations thereof.

Referring now to FIG. 8, an exemplary embodiment of the display support frame 152 may include seven support beams 154, 156, 158, 160, 162, 164, and 166. Four of the seven support beams 154, 156, 158, and 160 have an opposing support beam (e.g., top support beam 154 has an opposing bottom support beam 158, right-side support beam 156 has an opposing left-side support beam 160, etc.). Two of the support beams 162 and 164 are diagonal support beams. One of the support beams 166 is a display panel group 110 support beam, supporting display panels 108 individually and as a group 110. When assembled, the two diagonal support beams 162 and 164 are joined at a midpoint 168 of each of the two diagonal support beams 162 and 164.

In an exemplary embodiment, two of the four opposing support beams 154, 156, 158, and 160 may have an alignment notch 170 located at a midpoint of the respective support beam (e.g., beam 158). The alignment notch 170 may aid in alignment of the respective support beam (e.g., 124) during machining and assembly of the respective support beam and the alignment notch may be used to determine whether or not one or more strict tolerances of a dimension (e.g., width and/or height of modular unit 124) are being maintained during and after assembly. In another exemplary embodiment, all four of the opposing support beams 154, 156, 158, and 160 have an alignment notch 170.

In an exemplary embodiment, the seventh support beam 166, located at a midpoint of the top support beam 154 and the bottom support beam 158 is arranged to provide vertical support and to provide a support surface for one or more interlocking fingers (below) of an individual locking mechanism (below) of a respective display panel 108. It is noted that the exact number of support beams included in the display support frame 152 is not limiting. For example, those skilled in the art may determine other configurations of support beams involving fewer or more support beams, and such configurations are meant to be encompassed by the inventive concepts of the present disclosure. For instance, in some embodiments, only a single diagonal beam may be used, making six total support beams used for the display support frame 152.

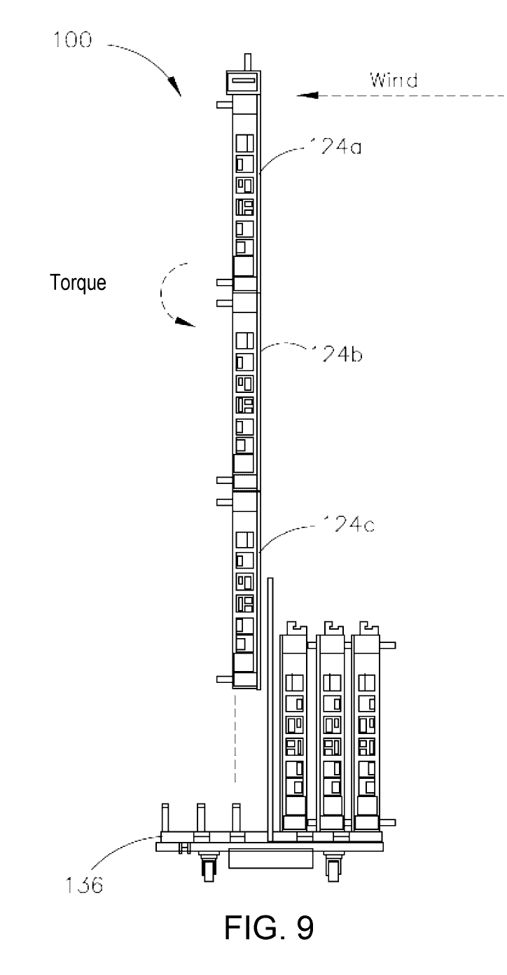

Referring now to FIG. 9, when multiple modular display units 124a, 124b, and 124c are linked together and are intended to rest upon the modular transport 136, it is noted that wind or other forces acting on a higher modular unit (e.g., 124a) may create torque with respect to the higher modular unit and a lower modular unit (e.g., 124b or 124c). In an exemplary embodiment, latches and other features of the modular interlocking display system 100 counter the torque. For example, referring now to FIG. 10, one feature that may act to counter the torque may include coupling one or more frame alignment guides 172a and/or 172b to the display support frame 152. In this regard, coinciding alignment guide holes 146 may be shaped together with the frame alignment guide 172 to restrict horizontal movement and torque. For instance, the frame alignment guide 172 may include a tapered, cylindrical shape used in conjunction with a circular-shaped or an elliptically-shaped alignment guide hole 146. It is noted that if an alignment guide 172a is placed on an opposite end of the top support beam 154 of the modular unit 124 as compared to another alignment guide 172b, an anti-torsion effect may also be created. It is further noted that in some embodiments, the alignment guide hole may be elliptically shaped to allow slight lateral shifting until a first modular unit (e.g., 124a of FIG. 10) is laterally interlocked with a second modular unit (e.g., 124d of FIG. 10).

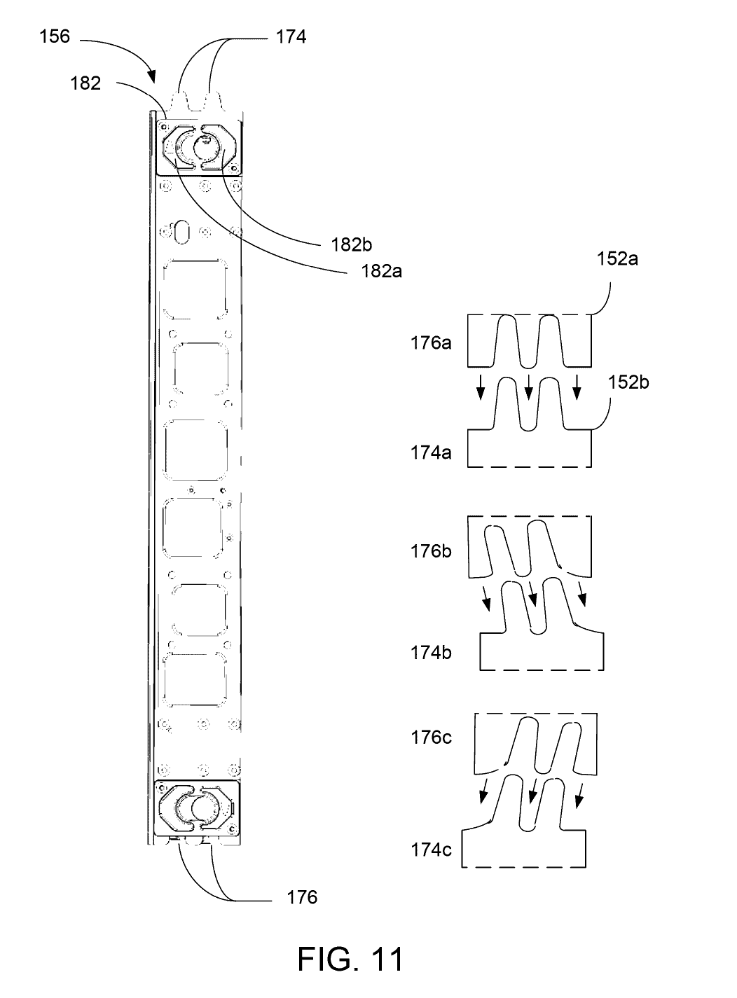

By way of another example, another feature that may act to counter the torque may include creating a finger-joint between two or more modular units 124. For instance, referring now to FIGS. 10 and 11, an exemplary embodiment of the right-side support beam 156 may be machined with two or more top protruding fingers 174 and two or more bottom finger depressions 176. A number and geometry of the finger depressions 176 will coincide with a number and geometry of the protruding fingers 174 used. For example if two fingers 174a having vertical symmetry are used for interlocking a support frame 152a with another support frame 152b, then two coinciding depressions 176a with vertical symmetry are used to coincide with the fingers 174a. By way of another example, if the geometry of the fingers 174b is left skewed, then the geometry of the of the depressions 176b may be coincidingly skewed, and if the geometry of the fingers 176c is right skewed, then the geometry of the depressions 176c may be coincidingly skewed. In this regard, if the number of the fingers 174 changes, then the number of the depressions will coincidingly change, providing a first keyed, registration support mechanism and another feature that creates an anti-torque effect.

In an exemplary embodiment, the fingers 174 and depressions 176 are rounded to allow quick alignment during assembly, and are tapered to allow rigid, interlocking support when assembled. It is noted that while the protruding fingers 174 are shown as located on a top surface of the side support beam 156 and the depressions 176 on a bottom surface of the side support beam 156, these positions may be reversed, and still be encompassed by the inventive concepts of the present disclosure. It is further noted that although fingers 174 and depressions 176 are depicted on right-side support beam 156, in order to maintain strict alignment and spacing tolerances, similar fingers 174 and depressions 176 will be formed on the left-side support beam 160.

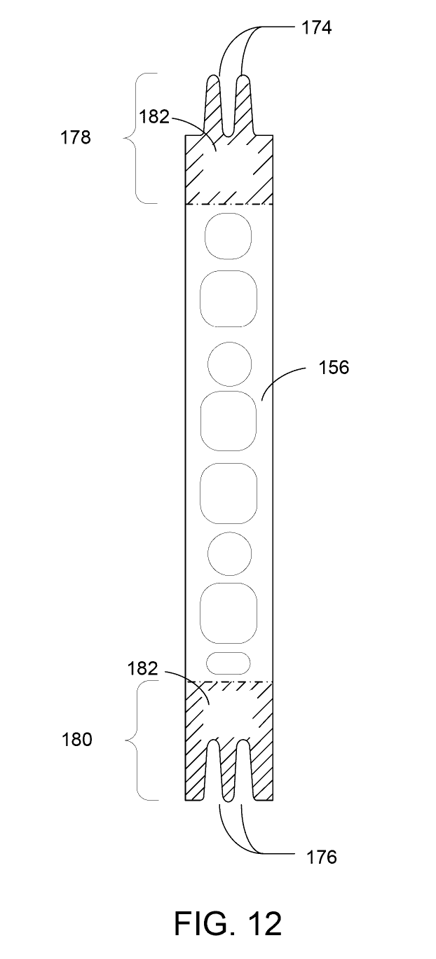

Referring now to FIGS. 11 and 12, in an exemplary embodiment, the right-side and left-side support beams 156 and 160 may be machined to have a first exterior portion 178 and a second exterior portion 180 of a respective support beam facial surface removed, wherein the term “exterior” is used with respect to an individual support frame 152 (i.e., the side support beam facial surface removed may be exterior with respect to an individual frame 152, but may be interior with respect to the entire modular interlocking display system 100 as a whole). In embodiments, the first exterior portion 178 and the second exterior portion 180 are removed via milling (e.g., face milling) after the support frame 152 is assembled. In embodiments, the removal of the first exterior portion 178 and second exterior portion 180 of facial surface may be a removal of 0.05-0.25 mm of facial surface material. In other embodiments, the removal of the first exterior portion 178 and second exterior portion 180 of facial surface may be a removal of 0.005-0.05 mm of facial surface material.

In an embodiment, the removal of the first exterior portion 178 and second exterior portion 180 of facial surface material allows for a second keyed, registration support mechanism (below) to be mounted on the exterior portions 178 and 180 of a side support beam (e.g., 156) after removal of excess material. The removal of excess material creates a rougher surface (e.g., as compared with other finished surfaces) for a more secure mounting of registration side-lock blocks 182 (e.g., mounted to a respective side support beam 156), while simultaneously maintaining the strict tolerances that are required during assembly and operation. Maintaining strict tolerances at every stage of design, manufacture and assembly, helps ensure that gaps between modular display panels 108 and deflection (e.g., when two or more panels meet at a seam and overlap or bubble up due to tight proximity or thermal expansion during use) between panels 108 is avoided or nonexistent, which contributes to the high resolution of the modular interlocking display system as a whole.

As previously mentioned, the support frame 152 may include at least a second keyed, registration support mechanism. In an exemplary embodiment, the second keyed, registration support mechanism may include multiple (e.g., four) registration side-lock blocks 182. The registration side-lock blocks 182 are keyed (e.g., implement a male key-like surface together with a female surface, similar to a keyseat) such that upon registration, the side-lock blocks 182 interlock with side-lock blocks of another support frame (not shown) to provide an additional level of registered alignment and rigidity. The geometry of the side-lock blocks 182 generally may include a tapered, male protruding surface used in conjunction with a tapered, depressed female surface. It is noted that the exact shape/contour of the side-lock block 182 is not limiting, provided it enables another keyed, registration support mechanism. For example, the registration side-lock block 182 may include a male, key-like lock block that may include a substantially circular, tapered protruding surface. The male registration side-lock block 182 is designed and manufactured such that when assembled, it will securely fit within a tapered depression of the female side-lock block (e.g., as with a keyseat). The taper of the protruding surface allows for quicker registration of the male and female surfaces. Again, the circular shape of the protruding surface of the registration side-block 182 is not limiting. For instance, the circular shape may be elliptical, square-shaped, or even asymmetrical; in these cases, the female depression would be shaped to coincide and register with the male protruding surface. In an exemplary embodiment, the added level of alignment and rigidity provided by the keyed registration side-lock blocks 182 may include a lateral alignment together with vertical and lateral rigidity due to the circular, tapered shape of the protruding and depression surfaces.

Referring again to FIG. 11, in another exemplary embodiment, the registration side-lock block 182 may include two different portions, including a first portion 182a that is a male, protruding portion and a second portion 182b that is a female, depression portion. As illustrated in FIG. 10, the substantially circular shape may include one or more angled surfaces, making the substantially circular shape more of an octagonal or hexagonal shape.

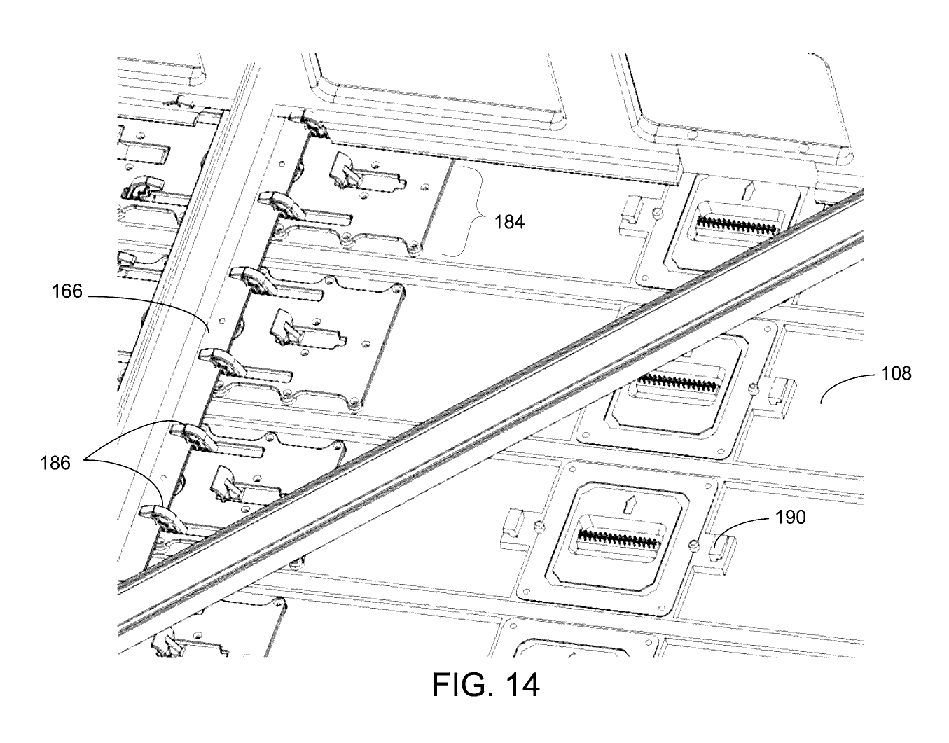

Referring now to FIGS. 13 and 14, in an exemplary embodiment, the support frame 152 may be configured to house one or more groups 110 of display panels 108 and a power supply 126. In another exemplary embodiment, the support frame 152 may be configured to house multiple groups 110 (e.g., two or more) of display panels 108.

In an exemplary embodiment, each display panel 108 may be secured to a respective support frame 152 via bi-level locking. Referring now to FIG. 14, a first level of the bi-level locking is an individual level obtained by an individual locking mechanism 184, which locks each panel 108 individually to the respective support frame 152. For example, an individual locking mechanism 184 may include one or more biased finger clamps 186, which may allow an individual display panel 108 to be individually secured to, and unsecured from, the respective support frame 152 (e.g., secured to the seventh support beam 166).

Referring now to FIGS. 14 and 15, a second level of the bi-level locking is a group locking level obtained by a group locking mechanism. The group locking mechanism may include the weather seal 134, lever 188 and one or more ear structures 190, wherein the one or more ear structures 190 are integral to each display panel 108. For example, referring now to FIG. 15, the weather seal 134 may include a sliding portion 192, such that as the lever 188 is rotated into a locking position, the sliding portion 192 slides substantially vertically. The sliding portion 192 may include tapered tabs 194 and cut-out portions 196. In an exemplary embodiment, a cut-out portion 196 may be dimensioned to allow an ear structure 190 to fit within (e.g., through) the cut-out portion 196, enabling a tab 194 to interlock with the ear structure 190 as the lever 188 is rotated and as the sliding portion 192 simultaneously slides to lock the weather seal 134 in place (e.g., via the tabs 194 and the ear structure 190 interlocking). In an exemplary embodiment, the tab 194 may be tapered and the ear structure 190 may be tapered at a similar angle to provide a tighter interlock as the tab 194 and ear structure 190 slidingly interlock.

In an exemplary embodiment, the weather seal 134, the lever 188 and the sliding portion 192 may be operatively secured to the support frame 152. For example, the lever 188 may be rotationally secured (e.g., secured while allowing rotational movement) and the sliding portion 192 may be slidingly secured (e.g., secured while allowing sliding movement) to the support frame 152.

Referring now to FIG. 16, an exemplary embodiment of an individual locking mechanism 184 may include a trigger release 196. The trigger release 196 may be configured to enable the one or more finger clamps 186 to move from an engaged position to a disengaged position. For example, the trigger release 196 may be engaged to remove a biasing force thereby disengaging the one or more finger clamps 186 from the support frame 152. In an exemplary embodiment, the trigger release 196 may disengage multiple finger clamps 186 simultaneously. For instance, finger clamps 186 may be located at two sides of the display panel 108 and the trigger release 196 may disengage the finger clamps 186 at each side at the same time. In another embodiment, a separate trigger release 196a and 196b may be provided for finger clamps 186 located at each side of the display panel 108 (see, for example, FIG. 17).

Referring now to FIGS. 8 and 18-20, an exemplary embodiment of the support frame 152 may include multiple (e.g., four) corner blocks 128. The corner blocks 128 are coupled to the support frame 152 via one or more fasteners (e.g., pre-tapped holes and fasteners, or self-tapping screws). The corner blocks 128 are utilized to removably integrate one or more latches 130 within the support frame 152 (e.g., the latches are removable from the corner blocks 128).

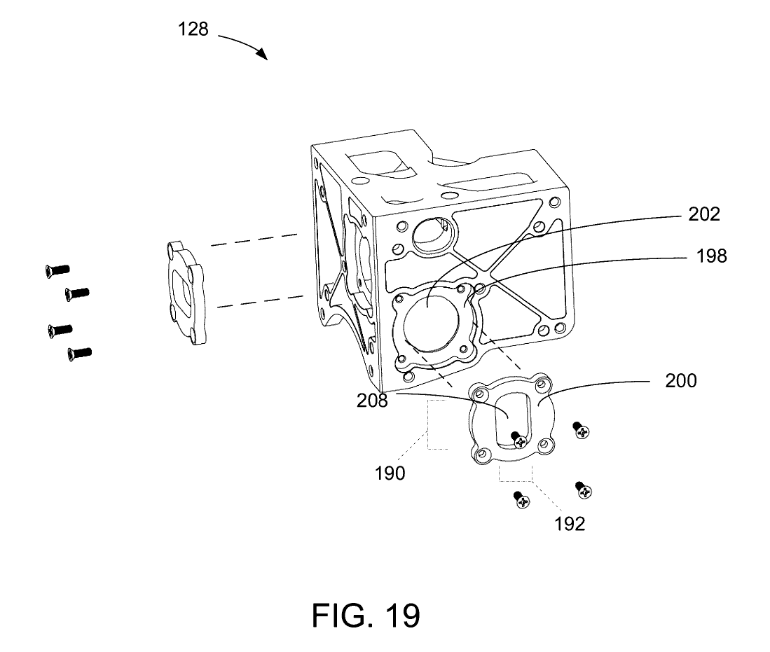

Referring now to FIGS. 19 and 20, an exemplary embodiment of a corner block 128 is depicted with a housing 198 (e.g., depressed portion) on an exterior surface of the corner block for a receiver plate 200 to be positioned therein. The corner block 128 may further include a cylindrical channel 202, extending through the corner block 128 such that a shaft 204 and shaft head 206 of the latch 130 may extend and retract within the cylindrical channel 202. The receiver plate 200 may be fastened to the housing 198 of the corner block 128 (e.g., pre-tapped hole and bolt/screw, or self tapping screws) at an exterior end of the cylindrical channel 202, such that a head of a second latch (e.g., latch of another support frame—not shown) may extend into and through a cut-out 208 of the receiver plate. It is noted that some embodiments of a corner block 128 may include only a receiver plate 200 instead of a receiver plate 200 and latch 130 combination, or two receiver plates 200 and one latch 130 instead of a two receiver plates 200 and two latches 130. It is further noted that the exact configuration of receiver plates 200 and latches 130 may vary, and may vary depending on how many modular display units 124 are integrated together in the modular interlocking display system 100 and a position of a respective modular unit 124 within the system 100.

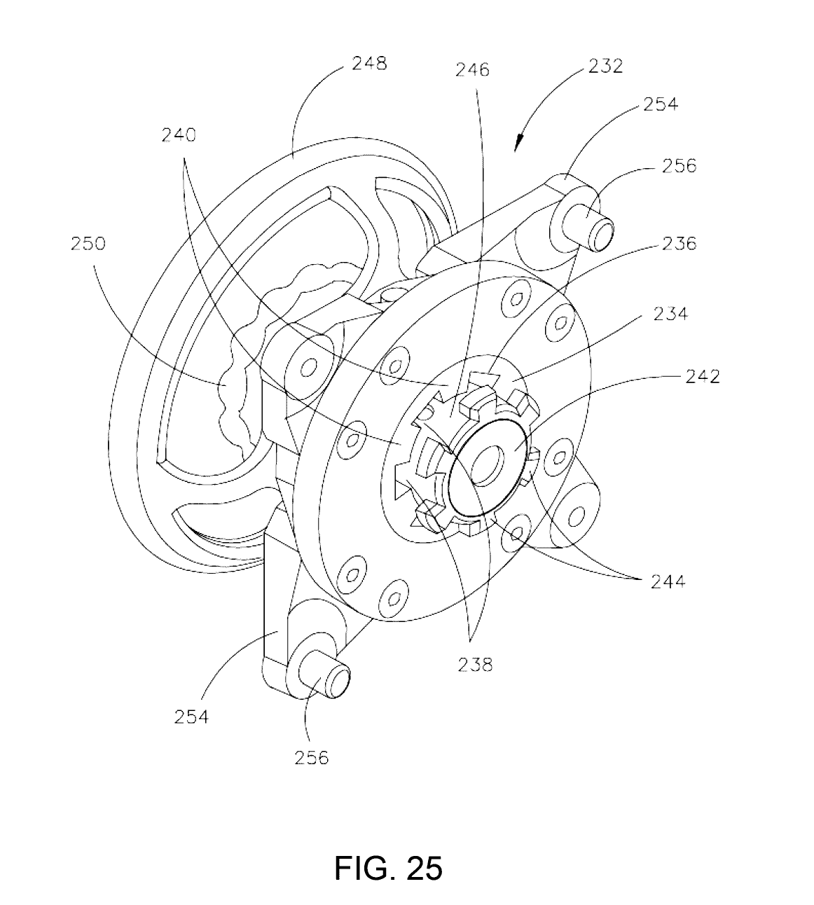

In an exemplary embodiment, the cut-out 208 of the receiver plate 200 of a first corner block 128 (e.g., of a first support frame) may have a slightly larger perimeter than a perimeter of the shaft head 206 of a second corner block 128 (e.g., of second support frame—not shown). Further, a shape of the cut-out 208 of the receiver plate 200 of the first corner block 128 may be substantially similar to a shape of the shaft head 206 of the second corner block 128 (not shown), allowing the shaft head 206 of the second corner block to extend through the cut-out 208 of the receiver plate 200 of the first corner block 128. In some embodiments, the cut-out 208 may have an elongated shape, with a vertical dimension 210 of the cut-out 208 smaller than a lateral dimension 212 of the cut-out 208. In other embodiments, the cut-out 208 has a symmetrical, gear-like shape (see, for example, FIG. 25). It is further noted that the precise shape of the cut-out 208 of the receiver plate 200 is not limiting. For example, any cut-out shape may be used that allows a shaft head (e.g., head 206 or shaft head shaped similar to the head in FIG. 25) to extend through the cut-out 208 opening, and further allows the shaft head 206 to revolve such that a back surface of the shaft head, after revolving and slightly retracting back, creates a bearing surface (e.g., creating shear forces) with an opposing surface of the receiver plate 200.

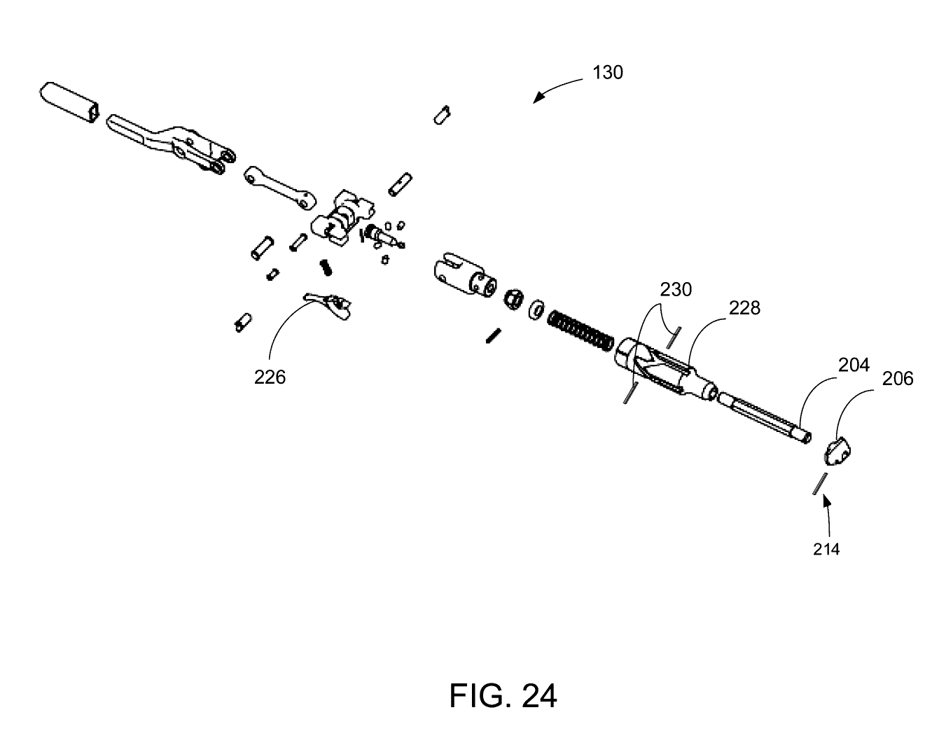

In an exemplary embodiment, the shaft head 206 may be adjustably coupled with the shaft 204. For example, the shaft head 206 may be tensioned to the shaft 204 using threads and/or screw head tensioning. In an exemplary embodiment, the shaft head 206 may include a pin 214 (FIG. 24) for restricting motion of the latch shaft head during operation (e.g., pin prevents the latch shaft head from being unscrewed and falling off during operation).

When assembled, the corner block 128 and latch 130 may provide a linking mechanism for securely and rigidly linking multiple modular display units 124 in a single direction. In an exemplary embodiment, two latches 130 may be arranged and attached substantially orthogonal to each other on a corner block 128, creating bi-directional linking for linking a corner block 128 to two other corner blocks 128 (i.e., each corner block of the two other corner blocks being coupled to a separate support frame) and allowing secure and rigid linking of modular display units 124 in multiple directions.

In an exemplary embodiment, the corner block 128 may further include a rounded depression 216 (FIG. 20) for receiving and coupling a rounded end of a diagonal support beam (e.g., 162 or 164 of FIG. 8) to the rounded depression 216 of the corner block 128.

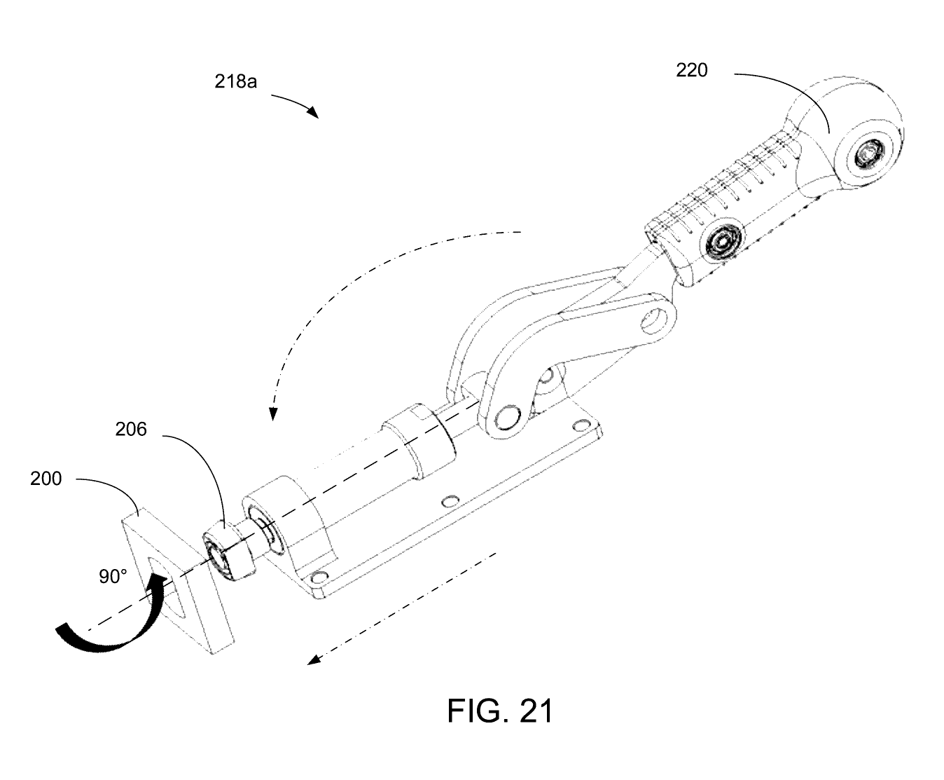

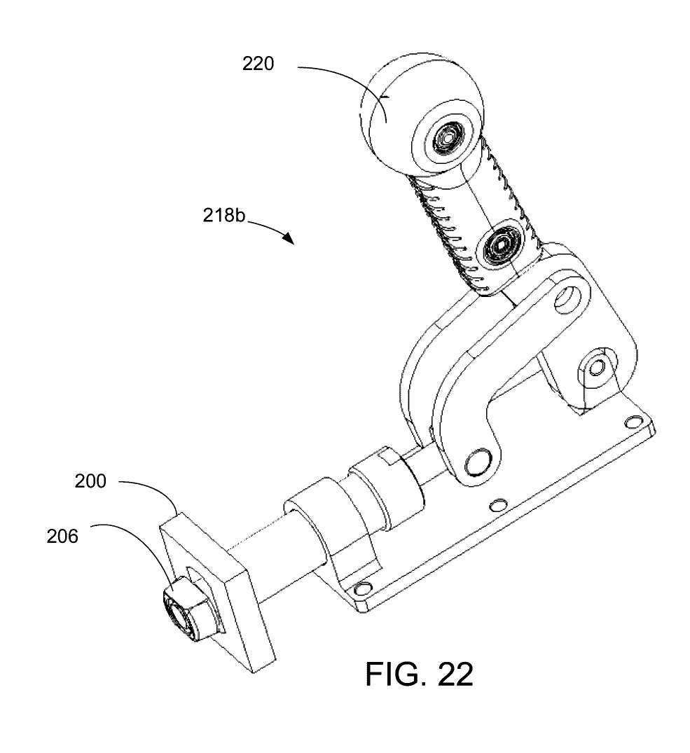

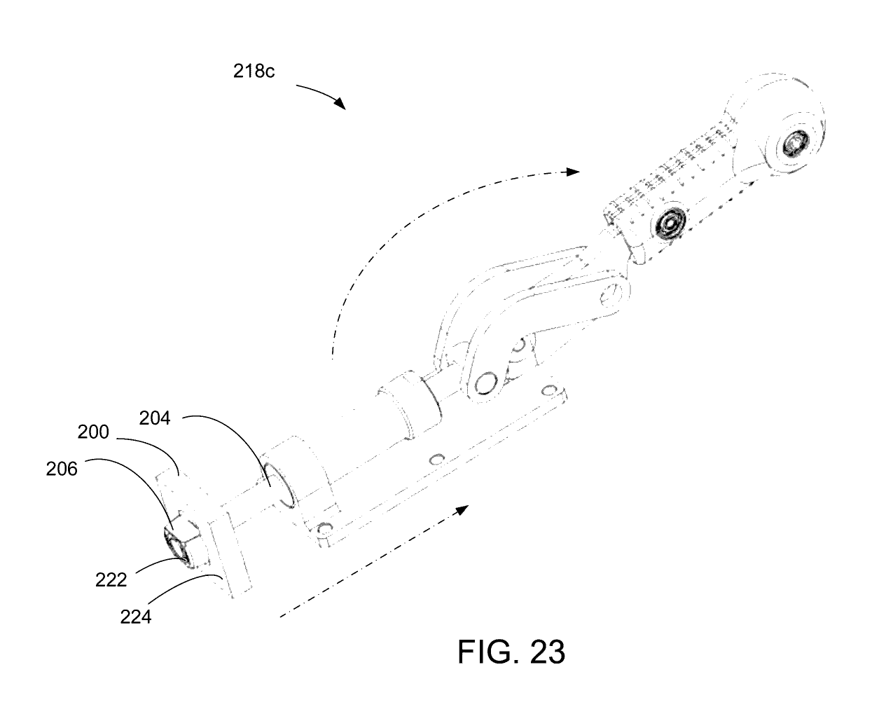

Referring now to FIGS. 20-23, in an exemplary embodiment, the latch 130 that is integrated within the support frame 152 is a revolving latch (e.g., revo-latch). The revo-latch 130 may revolve according to an expected magnitude of 90 degrees per revolution, simultaneously while a shaft head 206 of the revo-latch 130 may move in two directions (e.g., forward/extends and backward/retracts) substantially along a longitudinal axis (e.g., roll axis) of the revo-latch 130, causing the revo-latch 130 to assume different positions 218. For example, referring now to FIG. 21, a first position of the revo-latch 130 may be a first retracted position 218a, and the lever 220 may be utilized to move the revo-latch 130 to an extended position 218b (FIG. 22). Referring now to FIG. 22, after the lever 220 has been utilized to move the revo-latch 130 into an extended position and the shaft head 206 has extended through the receiver plate 200 simultaneous with a 90 degree rotation, the lever 220 may be utilized to move the revo-latch 130 to a second retracted position 218c (shown in FIG. 23). Referring now to FIG. 23, the revo-latch 130 may assume the second retracted position 218c to lock a bearing surface of the shaft head 206 (e.g., surface opposite to surface 222) against a bearing surface 224 of the receiver plate 200.

Referring now to FIG. 24, in an exemplary embodiment, the revo-latch 130 may include a trigger locking device 226. The trigger locking device 226 engages a portion of the support frame 152, such that when the revo-latch 130 is in a retracted position 218c (shown in FIG. 23), the trigger locking device 226 must receive a substantially linear force to release the trigger locking device 226 from the support frame 152 and move the revo-latch 130 from its second retracted position 218c into the extended position 218b. Moving the revo-latch 130 from its second retracted position 218c extends, revolves and retracts the shaft head 206 such that the shaft head 206 is rotated and retracted back through the receiver plate 200 to release the interlocking force of the revo-latch 130.

In an exemplary embodiment, the expected magnitude of ninety degree revolution is not limiting. For example, the revo-latch 130 may be configured to revolve according to an expected magnitude of 360/2N degrees each revolution, where N is a number of teeth of the shaft head 206 that extend beyond a circumference of the shaft 204. For instance, a shaft head having six teeth (e.g., shaft head similar to head shown in FIG. 25) that extend symmetrically beyond a circumference of the shaft may only need to revolve thirty degrees until a tooth of the shaft head is revolved sufficient enough that when retracted, the back surface of the tooth may create a bearing surface against an opposing surface of a similarly shaped receiver plate (not shown).

In an exemplary embodiment, the revolving motion of the revo-latch 130, while simultaneously extending forward or retracting back, may be obtained using a cam and follower pin configuration. For example, referring again to FIG. 24, a cylindrical cam 228 may include channels that allow cam follower pins 230 to follow along in the channels of the cam 228 such that as the shaft 204 of the revo-latch 130 extends forward, the cam follower pins 230 engage the channels of the cam 228 to rotate the shaft 204 and shaft head 206 (e.g., converting linear motion to rotational motion). In an exemplary embodiment, the cam follower pins 230 are integrated with a corner block 128 (see FIG. 18).

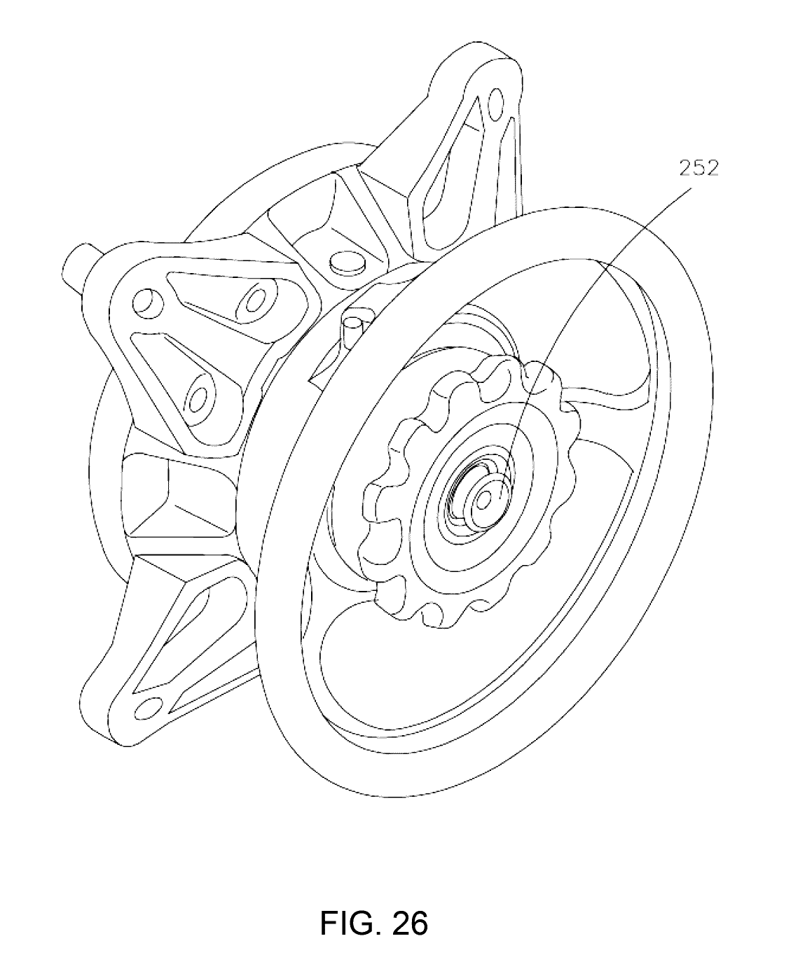

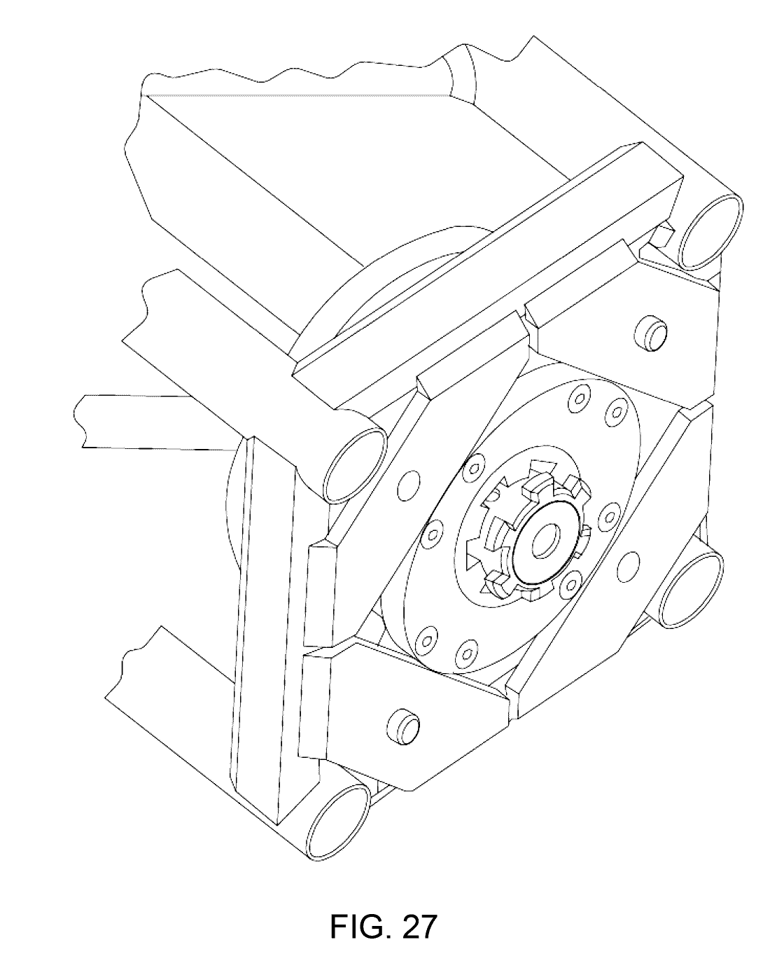

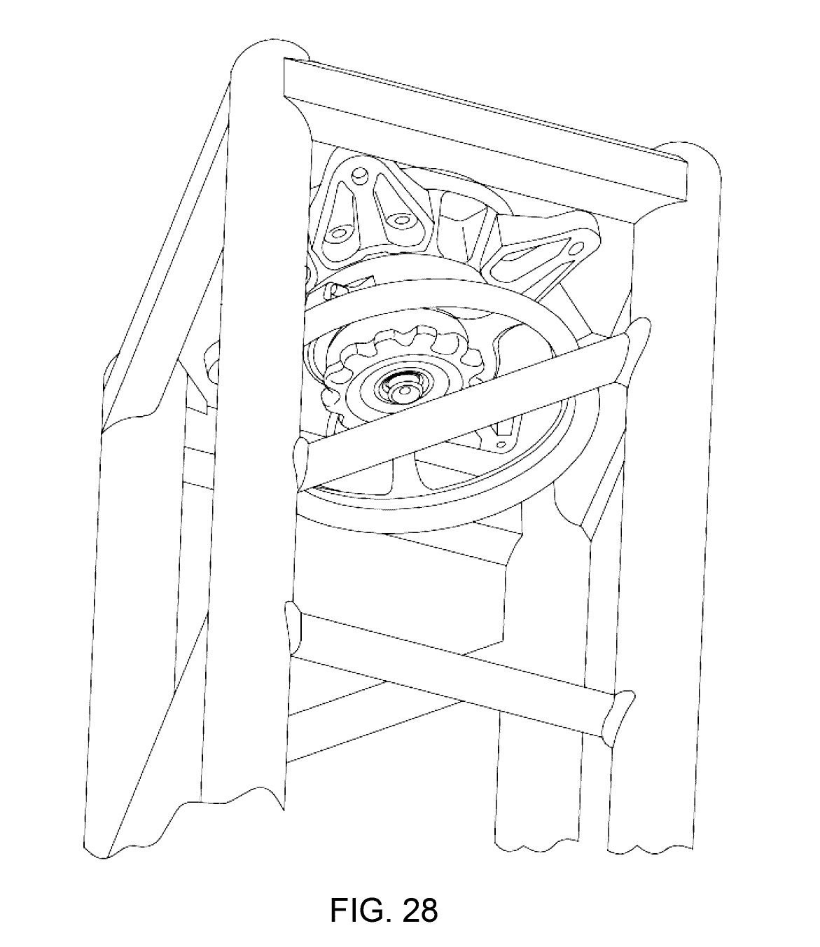

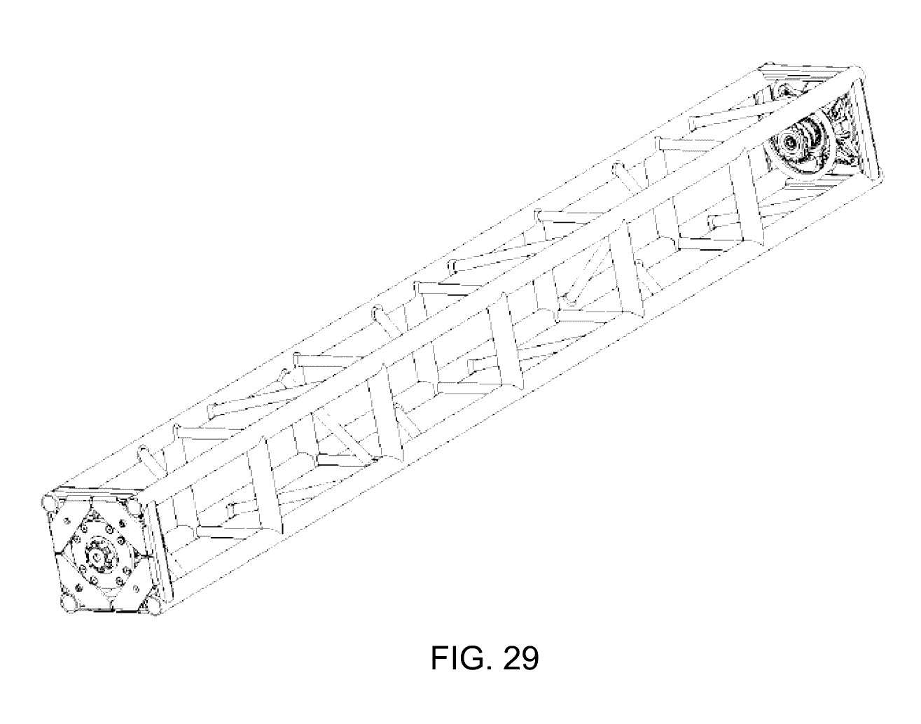

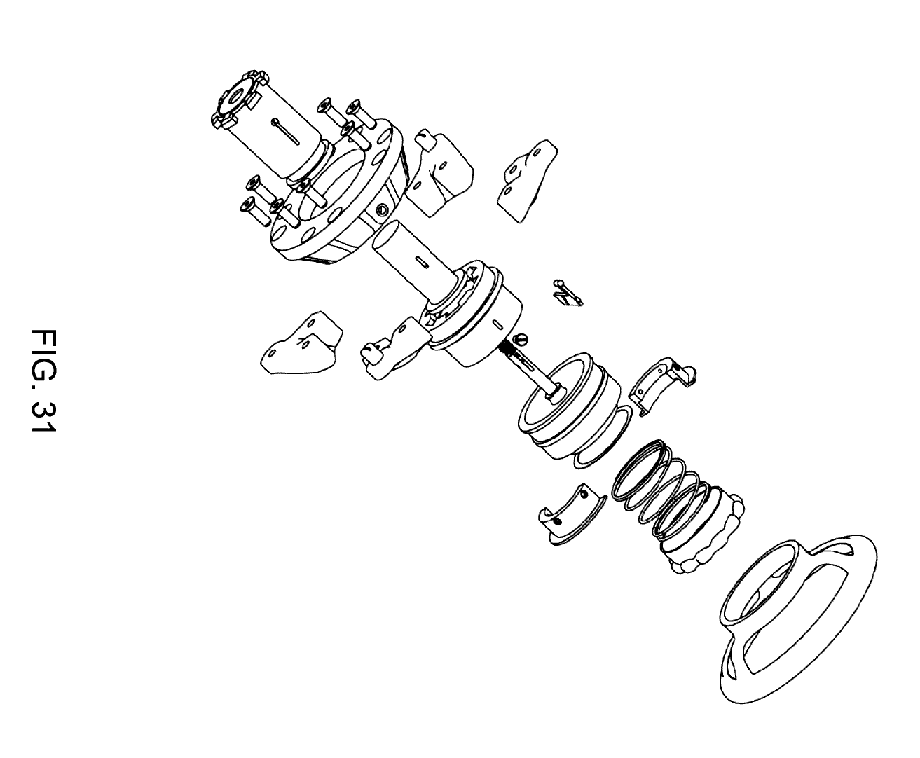

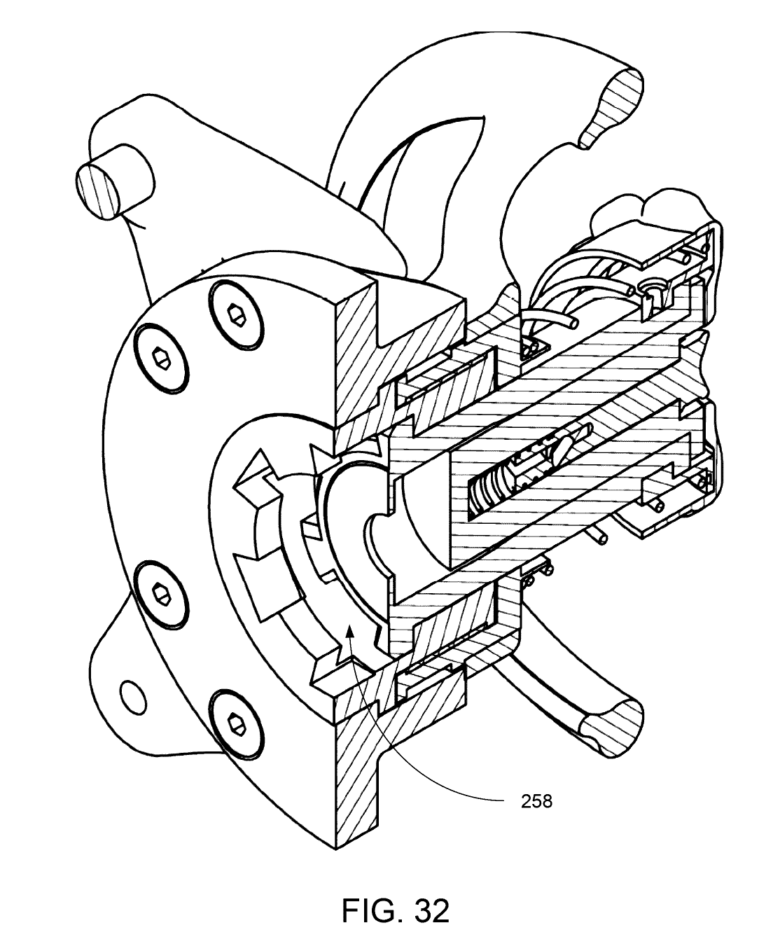

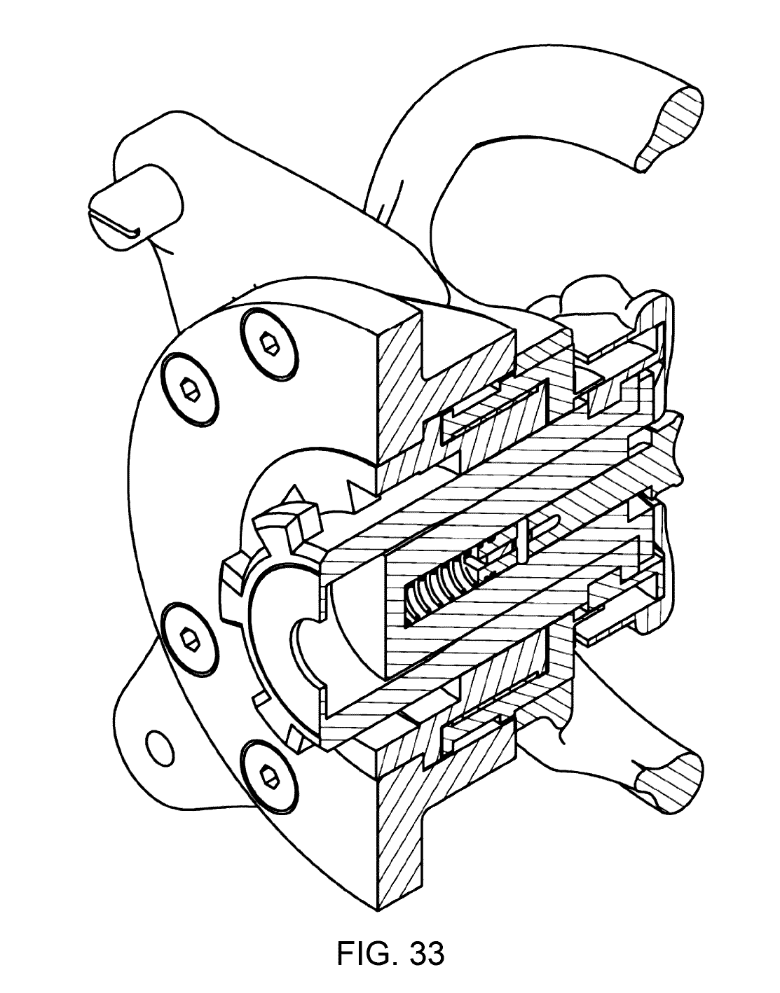

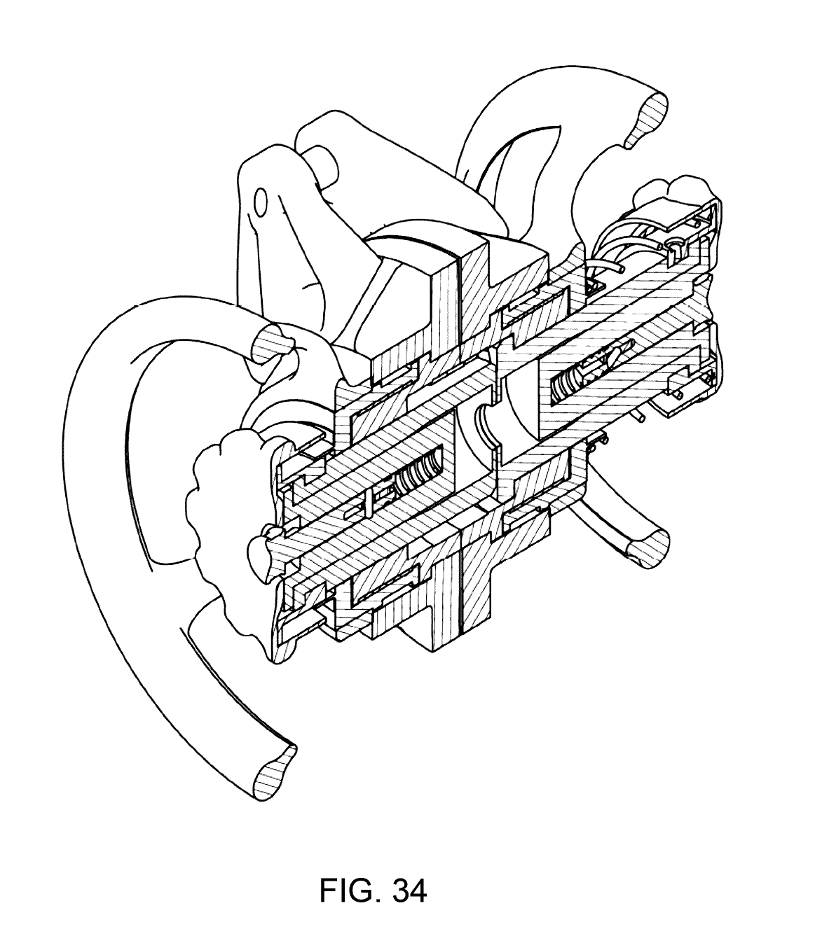

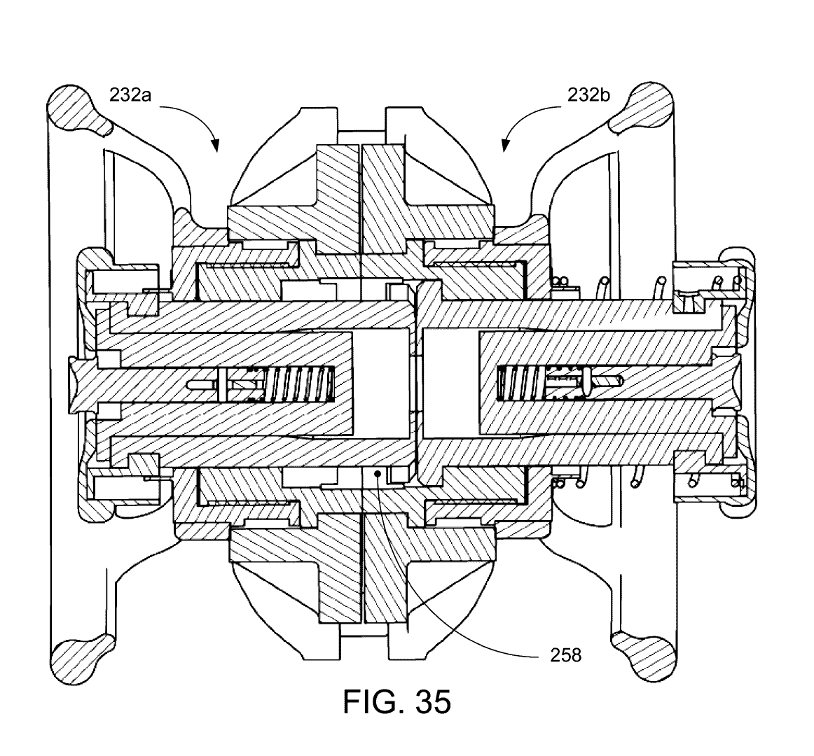

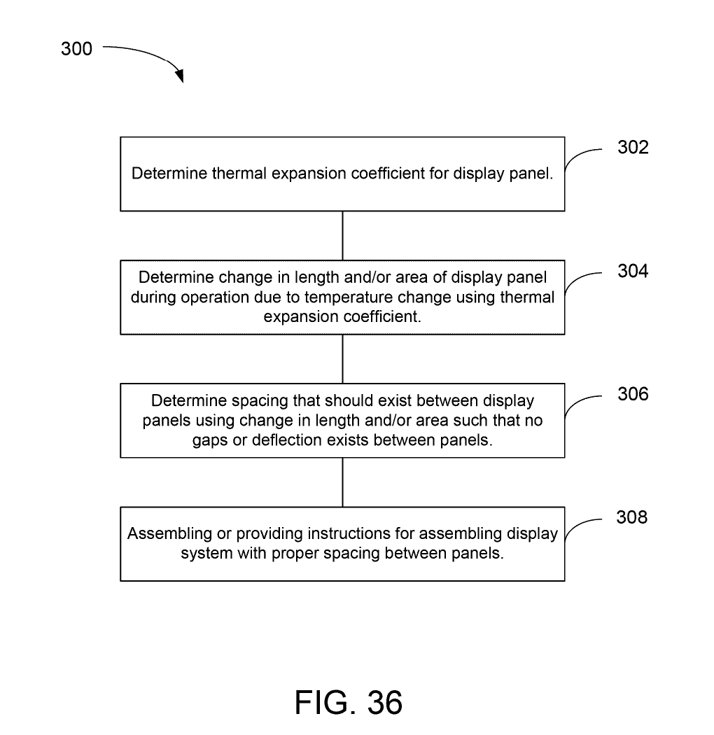

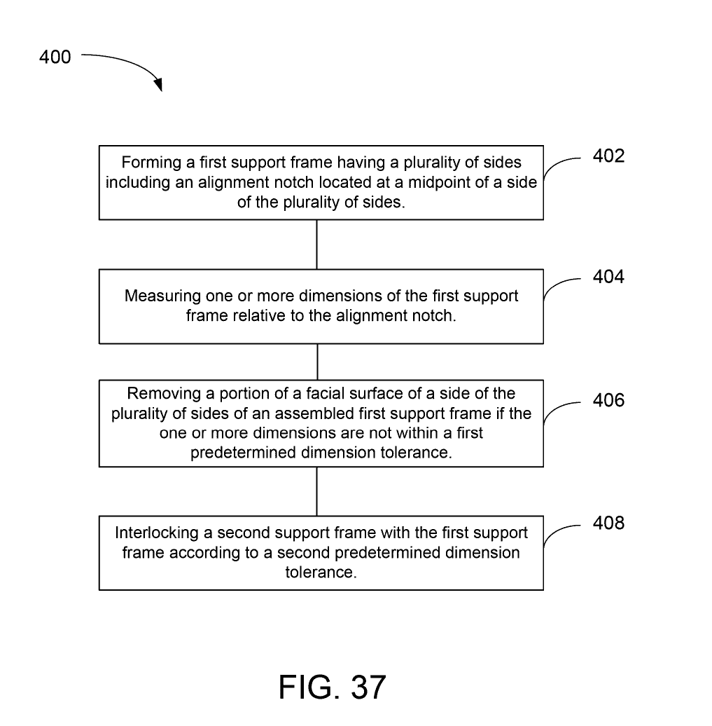

It is noted that exemplary embodiments disclosed herein depict a revo-latch 130 with a lever for moving the shaft head (e.g., 206) into and out of an extended and interlocked position. It is further noted that this depiction is not limiting. For example, a servo motor may be attached to extend and retract the cylindrical cam 228 such that the cam follower pins 230 engage and rotate the cam 228, thereby rotating the shaft head (e.g., 206). By way of another example, the shaft head may have several teeth (e.g., six—as the shaft head shown in FIGS. 25-40) and may be connected to an extendable, retractable and rotatable wheel (e.g., as shown in FIGS. 25-40). It is further noted that one or more servo motors may be used for all of extending, rotating, and retracting the shaft 204 and shaft head 206.

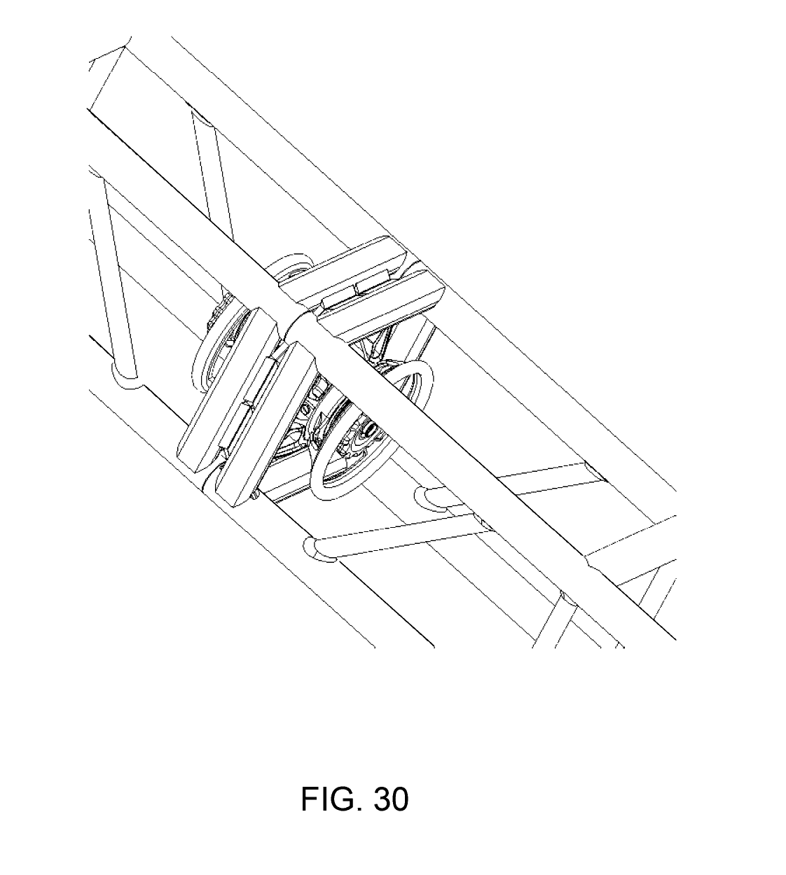

Referring now to FIGS. 25 through 42, latch 232 is depicted. In embodiments of the disclosure, two latches 232 can be mated together (e.g., to form a unisex latching system, which can lock two components together). The latches 232 can be used for applications including, but not necessarily limited to, support frames for modular interlocking display device 100, truss building (e.g., with twelve-inch (12″) trusses, twenty-inch (20″) trusses, etc.), or combinations thereof. For example, latch 232a and 232b (see FIG. 42) may form a latching system that can allow latch 232a and latch 232b to connect in either direction and improve the efficiency of building large truss structures and/or linking multiple support frames. Further, latch 232 may be used to connect and lock trusses together where pins and/or bolts were previously used. However, it should be noted that truss structures (see for example, FIG. 30) are provided by way of example and are not meant to limit the inventive concepts of the present disclosure. In other embodiments, latch 232 is used for other various applications, including applications where a unisex latching system connects two or more components together.

In some embodiments, a latch 232 may include a base 234 that defines an opening 236 having radially extending apertures 238 spaced apart from one another and extending from the center of the opening 236. It is noted that the base 234 may be an embodiment of a receiving plate. The latch device 232 also may include radially extending teeth 240 spaced between respective ones of the apertures 238 and extending toward the center of the opening 236. The latch 232 can also include a shaft head 242 having radially extending shaft head teeth 244 spaced apart from one another and extending from the center of the shaft head 242. The latch 232 can further include a shaft 246 coupled with the base 234 and configured to extend the shaft head 242 through the opening 236 when the shaft head teeth 244 are aligned with the apertures 238. For example, the shaft 246 can be threadably coupled with the base 234. A handle 248 may be included for advancing and retracting the shaft 246. In an exemplary embodiment, the handle 248 is in the shape of a wheel. In some embodiments, one or more cross pins can be used to create a stop that prevents the shaft 246 from being unthreaded from the base 234. In some embodiments, various components of a latch 232 can be fabricated using, for instance, hardened tool steel. In other embodiments, the various components of the latch 232 can be fabricated using a more light-weight, high-strength material (e.g., titanium alloy).

In operation, two latches 232 can be connected together to form a latching system. For example, two latches 232a and 232b may be placed adjacent to one another and axially aligned, and the shaft 246 of a second latch (e.g., 232b) may be retracted. Then, the shaft 246 of the other latch 232a may be extended through the opening 236 of the second latch 232b (e.g., when the shaft head teeth 244 of the first latch 232a are aligned with apertures 238 of both the first latch 232a and second latch 232b). Next, the shaft head 242 of the second latch 232 can be rotated so that the shaft head teeth 244 are no longer aligned with the apertures 238. For example, in some embodiments, a knob 250 may be fixedly connected to a shaft head 242, which is rotationally coupled with the shaft 246, and the knob 250 can be used to turn the shaft head 242 of the second latch 232 with respect to the shaft 246 so that the shaft head teeth 244 of the shaft head 242 align with the teeth 240 of the first latch 232. Then, the shaft 246 of the second latch 232 can be retracted into a receiving compartment 258 (see, for example, FIGS. 38 and 41) until the shaft head teeth 244 of the second latch 232 come into contact with the teeth 240 of the first latch 232, locking the two latches 232 together.

In some embodiments, the shaft head 242 may lock into an engaged orientation when the shaft head teeth 244 are aligned with the teeth 240. For example, a pin and slotted hole configuration can be used, with a button 252 that moves (e.g., extends, pops out) when the shaft head teeth 244 are aligned with the teeth 240. This example can use a coil spring, or another biasing mechanism, that can bias the button 252 to move outwardly when the shaft head teeth 244 and the teeth 240 are aligned. In this manner, the button 252 can provide an indication (e.g., a visual indication) that two latches 232 are locked together. For example, the button 252 can be formed in a specific color (e.g., green) and/or may include indicia or other visual indications that the shaft head 242 is locked in position. In some embodiments, to move the shaft head teeth 244 and the teeth 240 back out of alignment, the button 252 can then be pressed to unlock the shaft head 242.

In some embodiments, one or more latches 232 can be used for truss building (e.g., with latches 232 positioned at opposite ends of a truss). A latch 232 can be integrally formed with a truss, can be an aftermarket accessory for a truss, and so forth. In some embodiments, a truss can implement symmetrical registration features (e.g., pins) to prevent the trusses from moving (e.g., rotating) with respect to one another. In some configurations, a latch 232 can include corner wings 254, which can create separation between the bases 102 of two latches 232 that are locked together. In this manner, compression forces (e.g., six (6) tons of compression force) between two trusses can be maintained at the periphery of the latches 232 rather than between the bases 234. This configuration can allow the forces to act through the trusses in positions appropriate for the construction of the trusses. For example, bolted connections can be replaced with pins 256 extending from the corner wings 254 of latches 232, which can be used to lock the trusses together.

Referring now to FIG. 43, an exemplary embodiment of a method 300 according to the inventive concepts disclosed herein may include one or more of the following steps.

A step 302 may include determining a thermal expansion coefficient for the display panel 108. In one embodiment, the thermal expansion coefficient is determined by heating the panel (e.g., operating the panel and allowing the power supplied to be converted into thermal energy) and measuring the associated changes in length per length of the display panel 108 and changes in temperature.

In another embodiment, the thermal expansion coefficient may be determined based on the average composition of the material of display panel 108. For example, a milling and pulverizing process may be utilized together with a density separation method using tetrabromoethane (TBE) to separate light and heavy fractions of samples of the display panel 108 material. The light and heavy fractions may be filtered, dried and then analyzed using Energy Dispersive X-Ray Spectroscopy (EDX). For instance, using a process similar to the above process, a display panel 108 may be assumed to include primarily a printed circuit board (PCB) material, and the PCB material may be estimated to include an average composition of 4.36% carbon, 30.03% oxygen, 38.50% aluminum, 15.96% silicon, 0.25% sulfur, 6.80% copper and 4.11% tin. Thermal expansion coefficients may be determined based on the average composition. For example, thermal expansion coefficients, a, (e.g., at 20° C.×10−6K−1) for the elements from which the material is made may include: copper 16.5, aluminum 23.1, silicon 2.6, tin 22.0, and carbon 7.1. The thermal expansion coefficient for the material as a whole may then be determined by weighting the thermal expansion coefficients according to their respective percentages of composition.

A step 304 may include using the thermal expansion coefficient to determine a change in length and/or a change in area that the display panel will experience during operation. For example, a function according to the following may be used:

$${\int }_{{L}_{0}}^{L} \frac{d L}{L} = α {\int }_{{t}_{0}}^{t} d t$$

$$ln L {\vert}_{{L}_{0}}^{L} = α t {\vert}_{{t}_{0}}^{t} \\ ln L - ln {L}_{0} = α ( t - {t}_{0} )$$

$$ln \frac{L}{{L}_{0}} = α ( t - {t}_{0} )$$

$$L = {L}_{0} {e}^{α ( t - {t}_{0} )}$$

where L is the final length and L₀ is the initial length. For area, we may use the following:

$$\frac{d A}{d t} = {L}_{1} \frac{d {L}_{2}}{d t} + {L}_{2} \frac{d {L}_{1}}{d t}$$

$$where$$

$$\frac{1}{A} \frac{d A}{d t} = 2 α$$

$$A = {A}_{0} {e}^{2 α ( t - {t}_{0} )}$$

Thus, if the thermal expansion coefficient for the material was determined to be 11.64×10⁻⁶K⁻¹, and the change in temperature of the display panel 108 from room temperature (e.g., 20° C.) to operating temperature was determined to be 60° C., the final area and final lengths could be found to be:

A=(0.05 m²)e^{2(11.64*10}^{^{−6}}⁾⁽⁴⁰⁾

A=0.05005 m²

L=(0.1 m)e^{(11.64*10}^{^{−6}}⁽⁴⁰⁾

L=0.50023 m

L=(0.5 m)e^{(11.64*40}^{^{−6}}⁽⁴⁰⁾

L=0.10005 m

Thus, changes in area and/or length are in the realm of tenths and hundredths of millimeters.

A step 306 may include using the change in length or the change in area to determine spacing that should exist between display panels 104 during assembly, such that during operation, no deflection (e.g., bubble at the seam) and no gaps will be present between respective display panels 104 due to the thermal expansion that will occur.

A step 308 may include assembling, or providing instructions on assembling, the modular interlocking display system 100 such that proper spacing will exist during assembly, so that no gaps or deflection exist during operation. For example, two or more revo-latches 130 and four or more side-lock registration blocks 182 may be coupled and integrated with a support frame 152, such that two or more modular display units 124 may be cinched and interlocked together to maintain proper alignment, positioning, spacing and strict tolerances required during assembly and operation.

Referring now to FIG. 44, an exemplary embodiment of a method 400 according to the inventive concepts disclosed herein may include one or more of the following steps.

A step 402 may include forming a first support frame having a plurality of sides including an alignment notch located at a side of the plurality of sides. For example, the support frame 152 may include multiple side support beams (e.g., 154, 156, 158, and 160) with an alignment notch 170 located at a midpoint of one or more of the plurality of side support beams. The side support beams may be machined according to precise dimensions and a predetermined tolerance for the dimensions. For instance, side support beams may be machined to a predetermined tolerance of 0.0127 mm or 0.0005 inches.

A step 404 may include measuring one or more dimensions of the first support frame relative to the alignment notch. In some embodiments, the support frame may comprises multiple side support beams instead of a single-structured support frame. In these embodiments, step 404 may include assembling the multiple side support beams 154, 156, 158, and 160 together with multiple corner blocks 128 to form a first support frame 152. In an exemplary embodiment, the multiple corner blocks 128 implement multiple revolving latches 130 in order to interlock the first support frame 152a with a second support frame 152b and a third support frame (not labeled). In an exemplary embodiment, the interlocking of the first support frame 152a, the second support frame 152b and the third support frame is a multi-directional interlocking. For example, the interlocking may include a first revo-latch 130a positioned orthogonal to a second revo-latch 130b (see, for example, FIG. 20) to provide a lateral directional interlocking, while the second revo-latch 130b provides a vertical directional interlocking.

In an exemplary embodiment, the one or more dimensions measured may be one or more dimensions of a single frame. For example, the one or more dimensions may include, but is not limited to, a height, a width, a length, a hypotenuse, an angle between two sides, or combinations thereof.

The step 404 may include measuring the one or more dimensions of the assembled first support frame 152 using the alignment notch 170 of one of the support beams (e.g., 154 and 158 of FIG. 8) of the multiple side support beams (e.g., 152-166). In another embodiment, step 406 may include measuring one or more dimensions using two or more alignment notches 170 of two or more of the multiple side support beams. For example, a first alignment notch 170a may be provided in a bottom support beam 158 and a second alignment notch 170b may be provided in a top support beam 154. In order for the predetermined tolerances to be maintained, a first distance from the first alignment notch 170a to a first corner of a respective support frame 152 may be measured, as well as a second distance from the second alignment notch 172b to a second corner and/or the first corner of the respective support frame 152. After measuring the first and second distances, the frame is determined based on the first and second distances, to be within a predetermined tolerance or not to be within a predetermined tolerance.

A step 406 may include removing a portion of a facial surface of a side of the plurality of sides if one or more dimensions are not within a first predetermined dimension tolerance. In an exemplary embodiment, the determination of a frame 152 to be within or not within the first predetermined dimension tolerance is made after the frame is assembled. Thus, the removal of the facial surface of a side of the plurality of sides will be after compliance with the first predetermined dimension tolerance is determined.

In an embodiment, the removing of the facial surface may include removing an exterior portion (e.g., 178 and/or 180 of FIG. 12) of a facial surface of a side support beam 156 of the plurality of side support beams if a dimension (e.g., the first or second distance) of the one or more dimensions is not within the first predetermined dimension tolerance. For example, if the first distance was determined to be 0.002 mm offset from a nominal first distance, then an amount of exterior facial surface may be removed corresponding to the amount of offset. For instance, exterior surface of right-side beam 156 may be determined to be 0.002 mm wider than the beam 156 should be, thus 0.002 mm of exterior facial surface may be milled or removed from portion 178 of the right-side beam 156 such that a registration side-lock block 182 may be positioned in an area corresponding to the portion 178 removed.

In an exemplary embodiment, the first predetermined dimension tolerance is predetermined for a single support frame. For example, the first predetermined dimension tolerance may be a predetermined width or length of the single support frame 152.

A step 408 may include interlocking a second support frame with the first support frame according to a second predetermined dimension tolerance. In an exemplary embodiment, the interlocking is accomplished using one or more revo-latches 130, an alignment guide 172 and corresponding alignment guide hole 146, and a registration side-lock block (e.g., 182a) registering with a second registration side-lock block (e.g., 182c).

In an exemplary embodiment, the second predetermined dimension tolerance is predetermined for multiple (e.g., two or more), interlocked support frames 152 or multiple interlocked modular units 124. For example, the second predetermined dimension tolerance may be a predetermined width of two interlocked modular units 124a and 124d (e.g., see FIG. 10).

In an exemplary embodiment, the step 408 may further include aligning a second support frame 152c with the first support frame 152a using a first registration side-lock block 182a mounted on the area coinciding with the removed portion 178 of the side support beam (e.g., beam 156) of the first support frame 152a and further using a second registration side-lock block 182c mounted on a coinciding area of the second support frame 152c (see, for example, FIG. 10). For instance, a first registration side-lock block 182a may include a male portion and a second registration side-lock block 182c may include a female portion, such that an additional level of alignment and rigidity is obtained when the first registration side-lock block 182a and the second registration side-lock block 182c are brought together.

The step 410 may further include aligning the third support frame with the first support fame using an alignment guide 172 coupled to the first support frame 152a and an alignment guide hole 146 formed in a corresponding position of the third support frame (e.g., 152b).

It is to be understood that embodiments of the methods according to the inventive concepts disclosed herein may include one or more of the steps described herein. Further, such steps may be carried out in any desired order and two or more of the steps may be carried out simultaneously with one another. Two or more of the steps disclosed herein may be combined in a single step, and in some embodiments, one or more of the steps may be carried out as two or more sub-steps. Further, other steps or sub-steps may be carried in addition to, or as substitutes to one or more of the steps disclosed herein.

From the above description, it is clear that the inventive concepts disclosed herein are well adapted to carry out the objects and to attain the advantages mentioned herein as well as those inherent in the inventive concepts disclosed herein. While presently preferred embodiments of the inventive concepts disclosed herein have been described for purposes of this disclosure, it will be understood that numerous changes may be made which will readily suggest themselves to those skilled in the art and which are accomplished within the broad scope and coverage of the inventive concepts disclosed and claimed herein.

1. A modular display unit, comprising:
a support frame;
an interlocking latch coupled to the support frame;
an alignment guide positioned on a first side of the support frame and an alignment guide hole positioned on a second side of the support frame;
a registration side-lock block positioned on a side orthogonal to the first side of the support frame;
a group of modular display panels removably coupled with an interfacing power supply and removably coupled to the support frame;
a memory configured to store computer executable code; and
a controller in communication with the memory and the interfacing power supply, the controller configured to access the executable code to perform and direct rendering and presenting of a display on the group of modular display panels.

2. The modular display unit of claim 1, wherein a display panel of the group of modular display panels is hot swappable.

3. The modular display unit of claim 1, wherein the registration side-lock block is keyed to register a registration side-lock block of a second modular display unit.

4. The modular display unit of claim 1, wherein the registration side-lock block has a male portion and a female portion to register with respectively opposing female and male portions of a registration side-lock block of a second modular display unit.

5. The modular display unit of claim 1, wherein the alignment guide and the alignment guide hole provide two or more dimensions of alignment.

6. The modular display unit of claim 5, wherein the two or more dimensions of alignment comprise vertical alignment and horizontal alignment.

7. The modular display unit of claim 5, wherein the two or more dimensions of alignment are provided while allowing lateral shift, and wherein the alignment guide comprises a cylindrical shaft that is tapered at an aligning end of the cylindrical shaft, and the alignment guide hole has an elliptical shape.

8. A multi-support frame system, comprising:
a support structure comprising a plurality of support frames;
a first support frame of the plurality of support frames comprising a revolving, interlocking latch, an alignment guide to align the first support frame with a second support frame in a first direction, a registration side-lock block to align the first support frame with a third support frame in a second direction, and a side support beam having tapered fingers on a first end of the side support beam and coinciding depressions on a second end of the side support beam, the depressions coinciding in shape to the tapered fingers.

9. The system of claim 8, wherein the revolving, interlocking latch is a first revolving interlocking latch, the first support frame further comprising at least a second revolving, interlocking latch to interlock the third support frame in the second direction.

10. The system of claim 9, wherein a latch of the two or more interlocking latches is orthogonally positioned with respect to at least a second latch of the two or more interlocking latches.

11. The system of claim 8, further comprising a modular display unit transport having one or more transport alignment guides configured to integrate with an alignment guide hole of at least one of the first support frame, the second support frame, and the third support frame, and wherein at least one of the first support frame, the second support frame, and the third support frame are integrated with a group of modular display panels to form the modular display unit.

12. The system of claim 8, further comprising at least a second alignment guide and corresponding alignment guide holes, wherein the two or more alignment guides are positioned on opposite ends of a side of the first support frame and the two or more corresponding alignment guide holes are positioned on opposite ends of a corresponding side of the second support frame.

13. The system of claim 8, further comprising an alignment notch, positioned on at least one of: a midpoint of a top side of a support frame of the plurality of support frames, a midpoint of a bottom side of the support frame, a midpoint of a right side of the support frame, and a midpoint of a left side of the support frame.

14. The system of claim 8, wherein one or more groups of modular display panels are integrated with at least one of the first support frame, the second support frame, and the third support frame, and wherein a corresponding power supply is integrated with a respective support frame to provide the display.

15. The system of claim 14, wherein the one or more groups of modular display panels are integrated with the at least one of the first support frame, the second support frame, and the third support frame using bi-level locking.

16. The system of claim 15, wherein the bi-level locking comprises a first individual modular display panel locking mechanism configured to individually lock or unlock a first individual display panel, wherein a second individual modular display panel locking mechanism is configured to securely lock a second individual display panel while the first individual display panel is unlocked and removed.

17. The system of claim 16, wherein the bi-level locking comprises a group modular display panel locking mechanism configured to lock or unlock each display panel of a group of the one or more groups of modular display panels simultaneously.

18. The system of claim 17, wherein the group modular display panel locking mechanism comprises a weather seal, a sliding portion, and a lever, wherein the sliding portion comprises a plurality of tapered tabs and a plurality of cut-out portions, wherein a cut-out portion of the plurality of cut-out portions is dimensioned to allow an ear structure of a modular display panel of the one or more groups of modular display panels to fit within and through the cut-out portion, enabling a tapered tab of the plurality of tapered tabs to interlock with the ear structure as the lever is rotated and as the sliding portion simultaneously slides to lock the weather seal in place.

19. A method comprising:
forming a first support frame having a plurality of sides including an alignment notch located at a midpoint of a side of the plurality of sides;
measuring one or more dimensions of the first support frame relative to the alignment notch;
removing a portion of a facial surface of a side of the plurality of sides of an assembled first support frame if the one or more dimensions is not within a first predetermined dimension tolerance; and
interlocking a second support frame with the first support frame according to a second predetermined dimension tolerance.

20. The method of claim 19, wherein the first predetermined dimension tolerance is predetermined according to a single support frame dimension tolerance, wherein the second predetermined dimension tolerance is predetermined according to a multi-support frame dimension tolerance, and wherein the removing the portion of the facial surface of the side contributes to obtaining or maintaining the second predetermined dimension tolerance.

21.-47. (canceled)
